(19) United States
(12) Patent Application Publication
(10) Pub. No.: US 2025/0354057 A1
(43) Pub. Date: Nov. 20, 2025

(54) LIGHT EMITTING MATERIALS AND RELATED SYSTEMS AND METHODS

(71) Applicant: Massachusetts Institute of Technology, Cambridge, MA (US)

(72) Inventors: Moungi G. Bawendi, Cambridge, MA (US); Dimuthu Thanippuli Arachchi, Cambridge, MA (US); Ulugbek Barotov, Everett, MA (US)

(73) Assignee: Massachusetts Institute of Technology, Cambridge, MA (US)

(21) Appl. No.: 19/208,075

(22) Filed: May 14, 2025

Related U.S. Application Data
(60) Provisional application No. 63/648,092, filed on May 15, 2024.
(60) Provisional application No. 63/664,853, filed on Jun. 27, 2024.

(51) Int. Cl. C09K 11/02; C09K 11/06; H10K 50/11

(52) U.S. Cl. CPC C09K 11/025; C09K 11/06; C09K 2211/1018; H10K 50/11

(57) ABSTRACT

Supramolecular J-aggregate structures and related systems and methods are generally described. Certain aspects relate to supramolecular J-aggregate structures that are coated by an encapsulating material, such as silica. In certain embodiments, the supramolecular J-aggregate structures have relatively high quantum yields and/or relatively fast emissive lifetimes. Such structures can be incorporated into light emitting materials that are relatively bright and/or that refresh relatively quickly.

### RELATED APPLICATIONS

This application claims priority under 35 U.S.C. § 119(e) to U.S. Provisional Patent Application No. 63/664,853, filed Jun. 27, 2024, and entitled “Light Emitting Materials and Related Systems and Methods,” and to U.S. Provisional Patent Application No. 63/648,092, filed May 15, 2024, and entitled “Supramolecular J-Aggregate Structures and Related Systems and Methods,” each of which is incorporated herein by reference in its entirety for all purposes.

### GOVERNMENT SPONSORSHIP

This invention was made with government support under CHE2108357 awarded by the National Science Foundation. The government has certain rights in the invention.

### TECHNICAL FIELD

Light emitting materials and related systems and methods are generally described.

### SUMMARY

Light emitting materials and related systems and methods are generally described. Certain aspects are related to supramolecular J-aggregate structures and related systems and methods. Certain aspects relate to light emitting materials (e.g., supramolecular J-aggregate structures) that are coated by an encapsulating material, such as silica. In certain embodiments, the light emitting materials (e.g., supramolecular J-aggregate structures) have relatively high quantum yields and/or relatively fast emissive lifetimes. Such structures can be incorporated into light emitting materials that are relatively bright and/or that refresh relatively quickly. The subject matter of the present disclosure involves, in some cases, interrelated products, alternative solutions to a particular problem, and/or a plurality of different uses of one or more systems and/or articles.

Certain aspects are related to light emitting materials. In some embodiments, the light emitting materials have a quantum yield of greater than or equal to 83% and an emissive lifetime of less than or equal to 1 nanosecond at at least one temperature of from 20° C. to 25° C.

In certain embodiments, the light emitting material comprises a J-aggregate, wherein a quantum yield of the J-aggregate is greater than or equal to 83% at at least one temperature of from 20° C. to 25° C.

Some aspects are related to methods. In some embodiments, the method comprises establishing a solution comprising a molecular precursor of a J-aggregate and a molecule comprising a linker region and an initial coating material precursor; allowing the J-aggregate to form in the solution; mixing the solution and a secondary coating material precursor and a coating facilitator; and allowing the J-aggregate to become coated in a layer comprising a coating material from the initial coating material precursor and the secondary coating material precursor.

In certain embodiments, the method comprises establishing a solution comprising a molecular precursor of a J-aggregate and an amine-functionalized silane; allowing the J-aggregate to form in the solution; mixing the solution and an orthosilicate and ammonia; and allowing the J-aggregate to become coated in a layer comprising silica.

Other advantages and novel features of the present disclosure will become apparent from the following detailed description of various non-limiting embodiments of the disclosure when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present disclosure will be described by way of example with reference to the accompanying figures, which are schematic and are not intended to be drawn to scale unless otherwise indicated. In the figures, each identical or nearly identical component illustrated is typically represented by a single numeral. For purposes of clarity, not every component is labeled in every figure, nor is every component of each embodiment of the disclosure shown where illustration is not necessary to allow those of ordinary skill in the art to understand the disclosure. In the figures:

FIG. 1A shows a method of encapsulating J-aggregates, according to certain embodiments.

FIGS. 1B-1J show, according to some embodiments, results of an in situ two-step silica-encapsulation procedure and characterization of silica-encapsulated vs bare TDBC J-aggregates. FIGS. 1B-1C show (B) steady-state absorption and (C) emission spectra for bare and silica-encapsulated J-aggregates. Normalized spectra are provided in FIGS. 1H-1I. FIG. 1D shows DLS autocorrelation function: correlation coefficient as a function of time which describes the measured time-dependent fluctuations in light scattering intensity for bare and silica-encapsulated J-aggregates exhibiting smaller size for encapsulated J-aggregates. Normalized intensity distribution as a function of size is given under FIG. 1J. FIGS. 1E and 1F show cryo-TEM images of bare and silica-encapsulated J-aggregates, respectively, further confirming the smaller size distribution for silica-encapsulated J-aggregate sheets. Scale bar: 200 nm. FIG. 1G shows sample solutions of TDBC: A (left)—monomeric form in methanol: orange, B (middle)—J-aggregate form in water/methanol mixture (12:1 v/v): pink, C (right)—silica-encapsulated J-aggregates in aqueous solution: bright pink. Higher brightness in the J-aggregate sample to the right qualitatively indicates a higher fluorescence light output brought by silica-encapsulation. FIGS. 1H-1I show normalized absorption (FIG. 1H) and emission (FIG. 1I) spectra of bare and silica-encapsulated TDBC J-aggregates. FIG. 1J shows normalized intensity distribution as a function of size for bare and silica-encapsulated TDBC J-aggregates as reported by the DLS instrument.

FIGS. 2A-2J-B show, according to some embodiments, surface analysis of silica-encapsulated TDBC J-aggregate sheets. FIG. 2A shows a HAADF-STEM image of silica-encapsulated two-dimensional J-aggregate sheets. FIG. 2B shows an EDX elemental map showing the silicon (Si) distribution within the field of view in (A). FIG. 2C is an overlap of (A) and (B) for better visual identification of homogeneous silica-encapsulation on the surface of J-aggregate sheets. Scale bar: 1 μm. FIG. 2D shows an integral EDX spectrum with the starred peak corresponding to silicon. J-aggregate solution was dried on 200-mesh copper grids covered with quantifoil holey carbon support films. Sharp peaks for C and Cu are expected. TDBC monomer contains S and Cl. In addition to these elemental peaks, silicon making an appearance indicates the presence of silicon in the sample. FIGS. 2E and 2F show AFM images of bare and silica-encapsulated TDBC J-aggregates, respectively. The height profiles along the yellow two headed arrows on FIG. 2E and FIG. 2F are shown, respectively in FIG. 2G and FIG. 2H. The average thickness of a single J-aggregate sheet is approximately 2.7 nm while the formed silica coating on the surface adds an extra thickness of approximately 2 nm for the encapsulated J-aggregates. FIGS. 2I-A-2I-F show surface analysis of silica-encapsulated TDBC J-aggregate sheets. FIG. 2I-A shows high-angle annular dark-field scanning transmission electron microscopy (HAADF-STEM) image of silica-encapsulated J-aggregate sheets. Energy-dispersive X-ray spectroscopy (EDX) elemental map showing (FIG. 2I-B) silicon (Si), (FIG. 2I-C) chlorine (Cl), (FIG. 2I-D) oxygen (O) distribution within the field of view in (FIG. 2I-A). FIG. 2I-E shows overlap of FIG. 2I-B and FIG. 2I-C for better visual identification of homogeneous silica-encapsulation on the surface of J-aggregate sheets. Scale bar: 1 μm. FIG. 2I-F shows an integral EDX spectrum with the starred peak corresponding to silicon. FIGS. 2J-A-2J-B show molecular dimensions and monomer arrangement of TDBC where FIG. 2J-A shows the dimensions of TDBC monomer with most extended sulfobutyl chains as visualized from Avogadro molecule editor and visualizer. The approximate height and width were calculated to be 1.6 and 2.0 nm, respectively, by incorporating the above values with van-der-Waals radii of outer Cl, O and H atoms (H-1.2 Ao, O-1.4 Ao, Cl-1.75 Ao). In FIG. 2J-B, slippage (S) is calculated to be approximately 1.2 nm.

FIGS. 3A-3E show, according to some embodiments, structural model detailing the monomer arrangement within bare TDBC J-aggregate sheets. FIG. 3A shows the structure of TDBC monomer and its dimensions with mostly extended sulfobutyl groups obtained from the Avogadro molecule editor and visualizer. FIG. 3B shows an AFM topography image of a bare J-aggregate sheet. Scale: 1 μm. Schematic diagram illustrates the staircase arrangement of TDBC monomers and the slippage angle (α). FIG. 3C shows the height profile along the two-headed arrow in FIG. 3B. FIG. 3D shows an edge view of the structural model showcases vertical, anti-parallel, slightly staggered, and non-linear geometry of monomers, resulting in a ˜2.7 nm thickness, consistent with the experimental AFM sheet thickness measurement. FIG.

3E shows top view displays the monomer arrangement with the slip angle, caused by the lateral displacement of monomers. The arrow indicates the direction of aggregate growth. Bilaterally exposed sulfobutyl groups allow silica-encapsulation from both the top and bottom surfaces of J-aggregate sheets. FIG. 3E shows vertical, anti-parallel, and slightly staggered TDBC monomer arrangement. Both Atomic Force Microscopy (AFM) height measurements for J-aggregates and molecular dimensions together confirm the non-linear arrangement of monomers.

FIGS. 4A-4J-D show, according to some embodiments, structural stability and optical enhancement of TDBC J-aggregates through silica-encapsulation. Steady-state absorption for a dilution series of bare (FIG. 4A) and silica-encapsulated (FIG. 4B) TDBC J-aggregates. The dilution factors with respect to the initial TDBC dye concentration is mentioned in brackets. FIG. 4C shows J-aggregate/monomer ratio of integrated areas obtained from FIG. 4A and FIG. 4B as a function of dilution factor for bare and silica-encapsulated J-aggregates. The sharp fall in the J-aggregate/monomer ratio for bare J-aggregates upon 25 times dilution indicates the structural fragileness of bare-J-aggregates. Plot of integrated emission as a function of absorptance for rhodamine 6G and (FIG. 4D) bare J-aggregates from 3 times purified monomers using a previously established method, (FIG. 4E) silica-encapsulated J-aggregates from purified monomers, and (FIG. 4F) silica-encapsulated J-aggregates from monomers as received without any prior purification. Using the relative method, the QY is calculated to be 88% for J-aggregates from purified monomers, 98% for silica-encapsulated J-aggregates from purified monomers, and 86% for silica-encapsulated J-aggregates from monomers as received. Time-resolved fluorescence intensity of (FIG. 4G) bare J-aggregates from 3 times purified monomers (τ=184 ps), (FIG. 4H) silica-encapsulated J-aggregates from purified monomers (τ=234 ps), (FIG. 41) silica-encapsulated J-aggregates from monomers as received without any prior purification (τ=226 ps) with mono-exponential fits. Excitation wavelength: 565 nm. (J) Calculation of photoluminescence quantum yield of silica-encapsulated TDBC J-Aggregates. FIG. 4J-A shows absorbance spectra and FIG. 4J-B shows emission spectra of TDBC J-aggregates at different concentrations. FIG. 4J-C shows absorbance spectra and FIG. 4J-D shows emission spectra of R6G solutions in methanol at different concentrations. FIG. 4J-E shows excitation power of the fluorimeter as a function of wavelength. FIG. 4J-F shows a plot of integrated emission as a function of absorptance for R6G and TDBC J-Aggregates.

FIGS. 5A-5E show, according to some embodiments, temperature-dependent spectroscopy of silica-encapsulated TDBC J-aggregates in a dried sugar matrix. FIG. 5A shows temperature-dependent absorption and emission spectra revealing a blue shift, narrowing, and intensification of J-aggregate absorption as the temperature decreases. FIG. 5B shows temperature-dependent emission spectra revealing a blue shift, narrowing, and intensification of J-aggregate emission as the temperature decreases. Excitation wavelength: 532 nm. FIG. 5C shows a plot of peak absorption and emission energies as a function of temperature. FIG. 5D shows a plot of absorbance FWHM as a function of temperature. FIG. 5E is a plot of fluorescence FWHM as a function of temperature.

### DETAILED DESCRIPTION

Light emitting materials and related systems and methods are generally described. Certain aspects are related to supramolecular J-aggregate structures and related systems and methods. Certain aspects relate to light emitting materials (e.g., supramolecular J-aggregate structures) that are coated by an encapsulating material, such as silica. In certain embodiments, the light emitting materials (e.g., supramolecular J-aggregate structures) have relatively high quantum yields and/or relatively fast emissive lifetimes. Such structures can be incorporated into light emitting materials that are relatively bright and/or that refresh relatively quickly.

Some aspects are directed to methods of making J-aggregates and/or light emitting materials comprising J-aggregates. “J-aggregates” refer to supramolecular assemblies of organic molecules. The organic molecules that assemble to form the J-aggregates are generally referred to herein as, for example, aggregatable molecules or molecular precursors of J-aggregates. In certain cases, organic molecules assemble via non-covalent interactions, such as pi stacking, to form J-aggregates.

In some embodiments, the method comprises establishing a solution comprising a molecular precursor of a J-aggregate and a molecule comprising a linker region and an initial coating material precursor. A variety of J-aggregate molecular precursors can be used. In some embodiments, the J-aggregate molecular precursor can be a 2-dimensional molecule, including cyclic portions or other portions that allow the molecule to maintain a flat shape. One non-limiting example of a J-aggregate molecular precursor that can be used is 5,5′,6,6′-tetrachloro-1,1′-diethyl-3,3′-di(4-sulfobutyl)-benzimidazolocarbocyanine (TDBC). Other examples of J-aggregate molecular precursors that can be used include those with sulfonate groups, such as the benzothiazole cyanine dyes including Cy3-Et (formula I below), Cy5-Ph (formula II below), and Cy7-Ph (formula III below). Other molecular precursors are also possible.

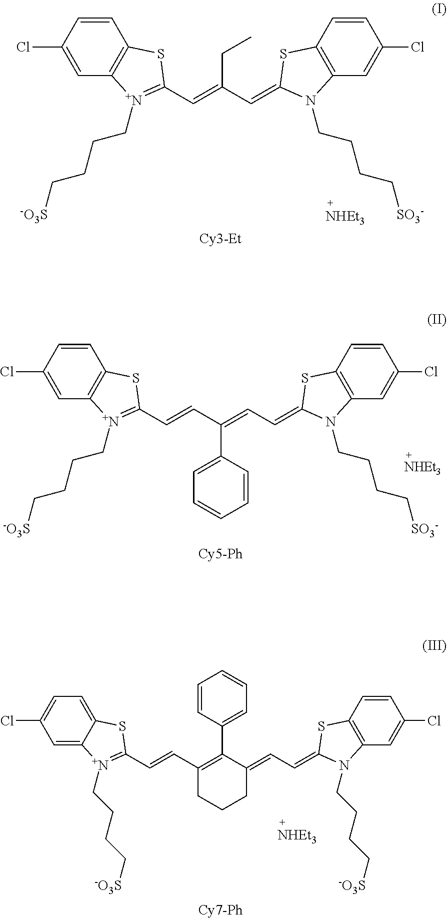

In some embodiments, the method further comprises purifying the molecular precursor of the J-aggregates, e.g., before establishing the solution. In some embodiments, a nuclear magnetic resonance (NMR) spectrum may be obtained from the solution containing the purified molecular precursor. In some embodiments, a ratio of the cumulative area under peaks associated with impurities to the cumulative area under the peaks associated with the molecular precursor is less than or equal to 1:4, less than or equal to 1:10, less than or equal to 1:50, less than or equal to 1:100, less than or equal to 1:500, less than or equal to 1:1,000, less than or equal to 1:10,000, less than or equal to 1:100,000, less than or equal to 1:107, less than or equal to 1:109, or less. For instance, in some embodiments, there may be substantially no impurities observable by NMR. Establishing a solution of molecular precursor of a J-aggregate may comprise providing a solution comprising a solvent and the molecular precursor of the J-aggregate, in accordance with some embodiments. Establishing a solution of molecular precursor of a J-aggregate may comprise providing a solution comprising the molecular precursor of the J-aggregate and a molecule having a linker region and an initial coating material precursor, in accordance with some embodiments. In certain embodiments, establishing a solution of a molecular precursor of a J-aggregate may comprise dissolving the molecular precursor of the J-aggregate in the solvent.

As noted above, the solution may, in some embodiments, comprise a molecule having a linker region and an initial coating material precursor. In certain embodiments, the molecule having a linker region and an initial coating material precursor can be a solute in the solution. In some embodiments, the linker region of the molecule that is contained in the solution can be configured to link (e.g., covalently, electrostatically, or otherwise) with a site on the J-aggregate molecular precursor. In some embodiments, the linker region of the molecule that is contained in the solution comprises a positively charged functional group in solution and/or a functional group capable of developing a positive charge when at equilibrium under standard conditions (e.g., at 1 atm of pressure and 25° C.). In some embodiments, the linker region comprises, for example, an amine functional group.

The association of the linker region of the molecule with the J-aggregate molecular precursor can bring the initial coating material precursor portion of the molecule relatively close to the J-aggregate molecular precursor, which can allow for the initial coating material precursor to form part of a coating around the J-aggregate, as described in more detail below. The initial coating material precursor of the molecule can be a precursor of, for example, silica, titania, hafnia, zirconia, alumina, or the like. In some embodiments, the initial coating material precursor comprises a silane. For example, in one set of embodiments, the molecule comprising the linker region and the initial coating material precursor comprises an amine-functionalized silane (in which the amine group is the linker region, and the silane is the initial coating material precursor). One example of an amine-functionalized silane that can be used is (3-aminopropyl) triethoxysilane (APTES). Accordingly, in some embodiments, establishing the solution comprises dissolving the molecular precursor of the J-aggregate in a solution containing an amine-functionalized silane.

In some embodiments, the solution comprises the molecule comprising a linker region and an initial coating material precursor as well as one or more types of solvent. Non-limiting example of solvents that can be employed include water, alcohols (e.g., methanol, ethanol, etc.), and combinations thereof in various ratios (e.g., greater than or equal to 1:1, greater than or equal to 1:10, greater than or equal to 1:12, greater than or equal to 1:20, greater than or equal to 1:30, greater than or equal to 1:40, and/or less than or equal to 1:50, less than or equal to 1:60, less than or equal to 1:70, less than or equal to 1:80, or less than or equal to 1:90). In some embodiments, solvent combinations may consist of two solvents, three solvents, four solvents, or more solvents, etc., in various ratios, and solvent combinations may be selected based on the ability of the solvent to solubilize the J-aggregate molecular precursor. In some embodiments, the solvent may comprise water and alcohol in a ratio of water to alcohol of greater than or equal to 1:10. According to some embodiments, the solvent may comprise a water and methanol in a ratio of greater than or equal to 1:12.

Certain embodiments comprise allowing the J-aggregate to form in the solution. Allowing the J-aggregate to form in the solution can comprise, for example, allowing the J-aggregate to form in the solution via self-assembly. In certain embodiments, during at least a portion of the self-assembly, the molecular precursor comprising the linker region may adsorb to or otherwise associate with the J-aggregate. For example, in certain embodiments, during at least a portion of the self-assembly, the amine-functionalized silane adsorbs to the J-aggregate. In accordance with some embodiments, the J-aggregate may be negatively charged while the molecule comprising the linker region and the initial coating material precursor may be positively charged (e.g., due to a positively charged functional group). In some such embodiments, and without wishing to be bound by any particular theory, it is believed that the molecule in solution associates with the J-aggregate due to electrostatic interactions. Such an interaction, in some embodiments, is believed to result in a relatively uniform coating of the molecule on the J-aggregate. Advantageously, the self-assembly of the J-aggregates and the adsorption of the initial coating molecule precursor thereon, in some embodiments, may occur, at least in part, at the same time. In some such instances, the coating during self-assembly may facilitate removal of additional impurities from the J-aggregate, compared to other J-aggregate assembly methods. Such simultaneous purification and coating can lead to J-aggregate structures exhibiting very high quantum yields and/or very fast emissive lifetimes, in accordance with certain embodiments.

Certain embodiments comprise mixing the solution comprising the J-aggregates, a secondary coating material precursor, and a coating facilitator. Similarly to the initial coating material precursor, in some embodiments, the secondary coating material precursor may be a precursor of, for example, silica, titania, hafnia, zirconia, alumina, or the like. The initial and secondary coating materials may be precursors of the same coating material, e.g., so that they may react together and/or separately to form the coating. The secondary coating material precursor can be, for example, a silicate such as an orthosilicate. In some embodiments, the secondary coating material comprises tetraethyl orthosilicate (TEOS). In some embodiments, the secondary coating material comprises tetraethyl orthotitanate, zirconium (IV) tetrapropoxide, a silicon alkoxide, a titanium alkoxide, and/or a zirconium alkoxide. The secondary coating material can, for example, add additional coating material to the coated J-aggregate. Adding the additional coating material can occur, for example, via reaction of the secondary coating precursor with the initial coating precursor. In some such embodiments, further addition of the secondary coating precursor (e.g., a second addition sequentially after a first addition and/or in a higher concentration) may result in additional coating material positioned over the J-aggregate.

The coating facilitator can be any material that initiates the formation of the coating on the J-aggregate from the initial coating precursor and the secondary coating precursor. In some embodiments, the coating facilitator is a reactant that reacts to form the coating on the J-aggregate. In certain embodiments, the coating facilitator is a catalyst that catalyzes a reaction that results in the formation of the coating on the J-aggregate. In some embodiments, the coating facilitator may catalyze a reaction between the initial and secondary coating material precursors to form the coating on the J-aggregate. In some embodiments, the coating facilitator may catalyze a reaction of the initial and/or the secondary coating material precursors to form the coating on the J-aggregate. The coating initiator can be, for example, ammonia (e.g., aqueous ammonia). In some embodiments, the coating facilitator may be an alkaline solution. For example, in some embodiments, the coating facilitator may be a solution comprising potassium hydroxide and/or sodium hydroxide. In some embodiments, the coating initiator is a basic molecule that may catalyze a reaction between the initial and secondary coating material precursors. Advantageously, in some embodiments, the coating facilitator may further prevent agglomeration of J-aggregate precursors in ways that inhibit quantum yield. For example, the use of ammonia (e.g., aqueous ammonia) has been found to be very effective in preventing agglomeration of J-aggregate precursors, in accordance with certain embodiments. Without wishing to be bound by any particular theory, it is believed that the use of coating facilitators like ammonia (e.g., aqueous ammonia) may create an electrostatic screen layer between J-aggregate precursor molecules, which may inhibit or prevent agglomeration of J-aggregate precursor molecules in ways that limit quantum yield.

Some embodiments comprise allowing the J-aggregate to become coated in a layer comprising a coating material from the initial coating material precursor and/or the secondary coating material precursor. This can occur, for example, by allowing a reaction between the initial coating precursor and the secondary coating precursor. In some such embodiments, allowing such a reaction may occur in the presence of a coating facilitator. The coating may comprise silica, titania, zirconia, hafnia, and/or alumina, in some embodiments, and may be determined by the identity of the initial and/or secondary coating material precursors. In some embodiments, allowing the J-aggregate to become coated in a layer comprising a coating material comprises hydrolyzing an amine-functionalized silane and an orthosilicate with ammonia (e.g., aqueous ammonia). In certain embodiments, allowing the J-aggregate to become coated in a layer comprising silica comprises crosslinking hydrolyzed amine-functionalized silane and hydrolyzed orthosilicate.

In one particular set of embodiments, the method comprises establishing a solution of a molecular precursor of a J-aggregate in a solution comprising an amine-functionalized silane;

allowing the J-aggregate to form in the solution; mixing the solution and an orthosilicate and ammonia (e.g., aqueous ammonia); and allowing the J-aggregate to become coated in a layer comprising silica.

In some embodiments, some or all of the method steps described above may be performed in darkness (i.e., in an environment in which little or no visible light is present). In some embodiments, it is desirable to avoid exposing a solution containing the molecular precursors and/or any J-aggregates formed therefrom to electromagnetic radiation having a wavelength that may be absorbed by the molecular precursors and/or J-aggregates (e.g., electromagnetic radiation having a wavelength of less than or equal to 650 nm, less than or equal to 600 nm, less than or equal to 550 nm, less than or equal to 500 nm, or less than or equal to 450 nm). In some embodiments, electromagnetic radiation having a wavelength of less than or equal to 650 nm, less than or equal to 600 nm, less than or equal to 550 nm, less than or equal to 500 nm, or less than or equal to 450 nm may be absorbed by the molecular precursors and/or J-aggregates formed therefrom. Avoiding exposing the molecular precursors to the J-aggregates and/or the J-aggregates to light may advantageously extend the lifetime of the molecular precursors and/or the J-aggregates, in accordance with some embodiments. In some embodiments, some or all of the method steps may be performed in a low-light environment, e.g., a dark room. In some embodiments, a container containing the solution containing the molecular precursors and/or the J-aggregates may be opaque and/or may be surrounded by an opaque material (e.g., Al foil) to limit and/or prevent exposure to light.

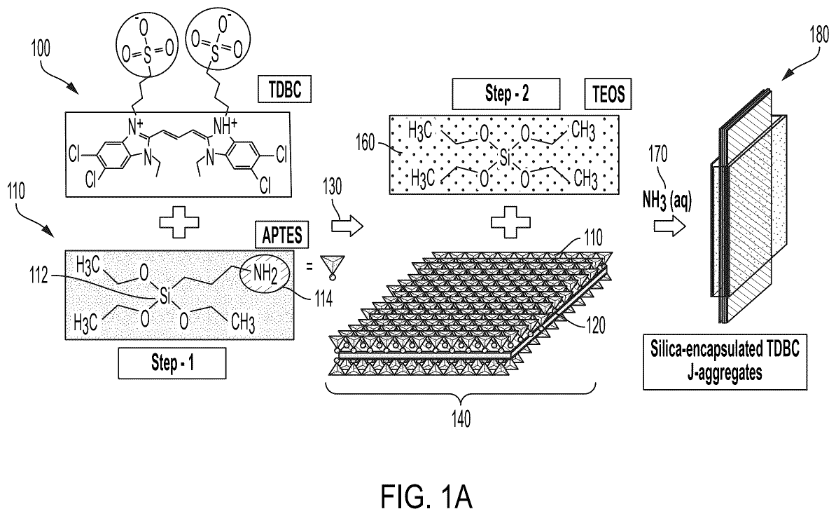

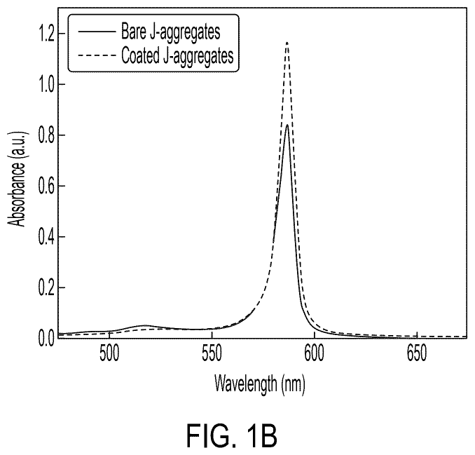

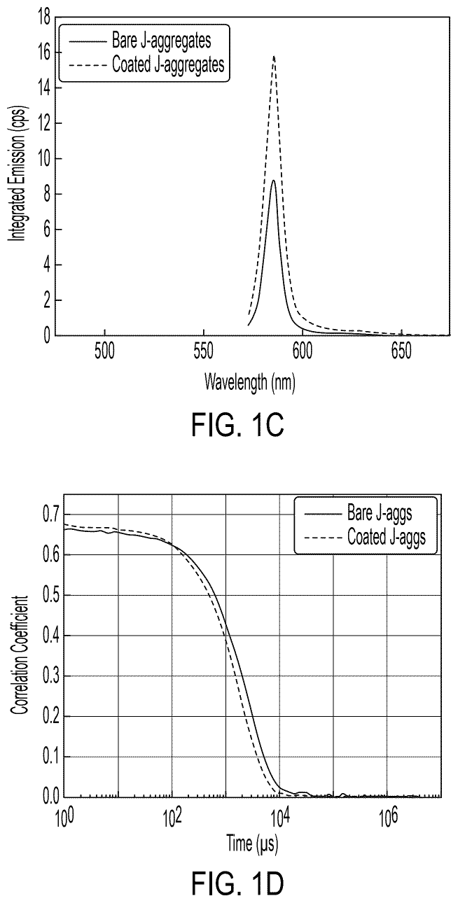

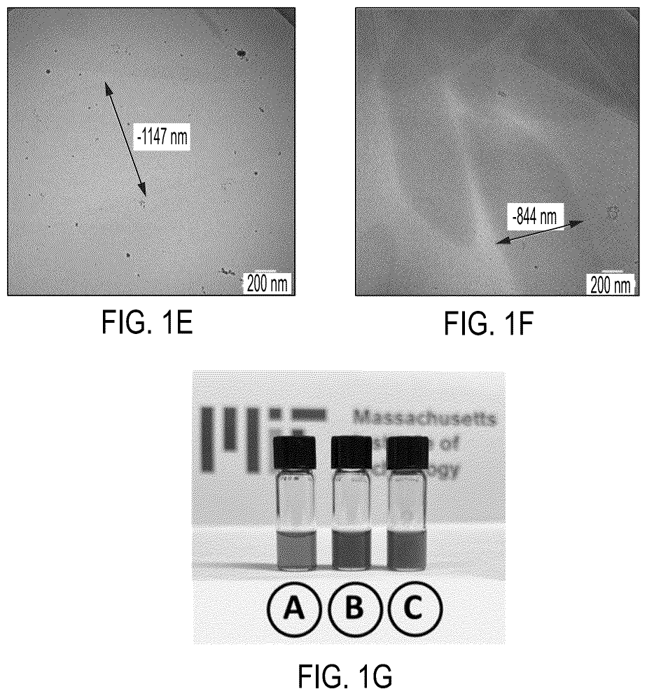

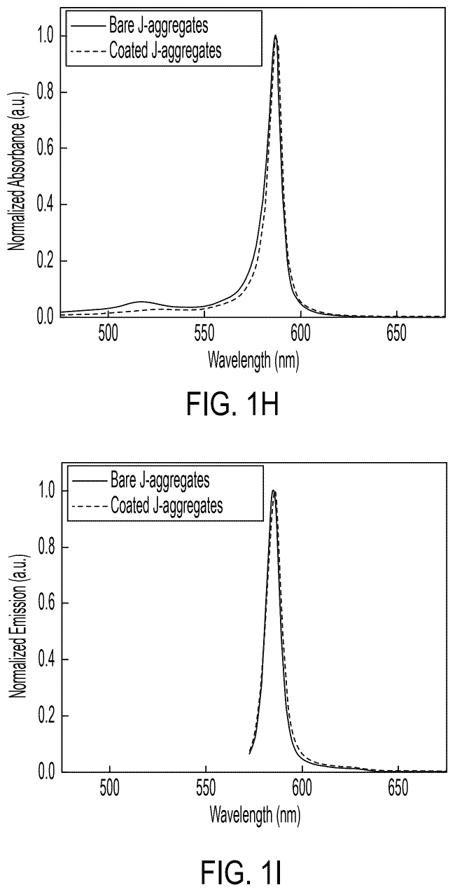

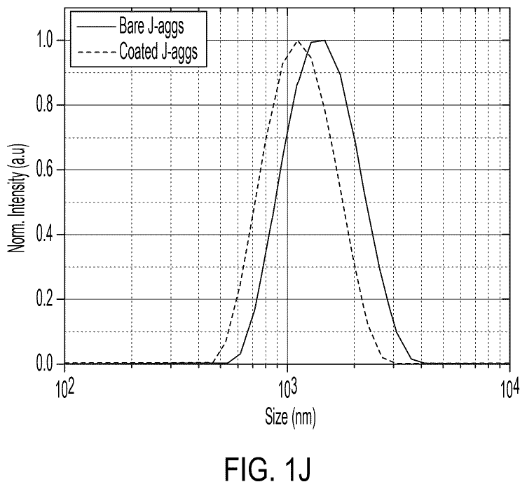

A non-limiting example of a method described herein is shown in FIG. 1A. FIG. 1A is a schematic diagram of a two-step silica-encapsulation procedure performed in the presence of aqueous ammonia. The method includes establishing a solution by mixing a J-aggregate molecular precursor 100 with a molecule 110 comprising an initial coating material precursor 112 and a linker region 114 to allow the molecular precursor 100 and molecule 110 to form a J-aggregate 120 coated with the molecule 110. The coated J-aggregate is shown as element 140 in FIG. 1A. As shown in FIG. 1A, the molecular precursor of the J-aggregate is in the form of 5,5′,6,6′-tetrachloro-1,1′-diethyl-3,3′-di(4-sulfobutyl)-benzimidazolocarbocyanine (TDBC), but as noted above, other J-aggregate precursors could be used. Also as shown in FIG. 1A, the molecule comprising the initial coating material precursor and the linker region is (3-aminopropyl) triethoxysilane (APTES) (and, accordingly, the linker region is an amine functional group and the initial coating material precursor is siloxane) but as noted above, other molecules could be used.

In accordance with some embodiments, referring again to FIG. 1A, the coated J-aggregate 140 is mixed with a secondary coating material precursor 160 and exposed to a coating initiator 170 to form a silica-coated J-aggregate 180. As shown in FIG. 1A, the secondary coating material precursor is tetraethyl orthosilicate (TEOS), but as noted above, other secondary coating material precursors could be used. Also as shown in FIG. 1A, the coating initiator is aqueous ammonia, but as noted above, other coating initiators could be used.

Certain aspects of the present disclosure are related to light emitting materials (e.g., light emitting materials that can be made using methods described herein). In some embodiments, the light emitting materials comprise a J-aggregate. In some embodiments, the light emitting material comprises a plurality of J-aggregates.

The J-aggregates and/or light emitting materials described herein may be any of a variety of sizes, in accordance with some embodiments. A size (e.g., a thickness, length, and/or width) of a J-aggregate may be determined using methods such as, for example, cryo-transmission electron microscopy, atomic force microscopy, or dynamic light scattering measurements. In some embodiments, a maximum thickness of the coated J-aggregate may be less than or equal to 100 nm, less than or equal to 90 nm, less than or equal to 80 nm, less than or equal to 70 nm, less than or equal to 60 nm, less than or equal to 50 nm, less than or equal to 40 nm, less than or equal to 30 nm, less than or equal to 20 nm, or less than or equal to 10 nm. In some embodiments, a maximum length and/or a maximum width of a coated J-aggregate may independently be greater than or equal to 10 nm, greater than or equal to 50 nm, greater than or equal to 100 nm, greater than or equal to 200 nm, greater than or equal to 300 nm, greater than or equal to 500 nm, greater than or equal to 750 nm, greater than or equal to 1,000 nm, or greater than or equal to 1,500 nm. In some embodiments, a maximum length and/or a maximum width of a coated J-aggregate may independently be less than or equal to 2,000 nm, less than or equal to 1,500 nm, less than or equal to 1,000 nm, less than or equal to 750 nm, less than or equal to 500 nm, less than or equal to 300 nm, less than or equal to 200 nm, less than or equal to 100 nm, or less than or equal to 50 nm. Combinations of the foregoing ranges are possible (e.g., greater than or equal to 1,000 nm and less than or equal to 1,500 nm, greater than or equal to 10 nm and less than or equal to 2,000 nm).

In some embodiments, the light emitting materials comprise one or more two-dimensional J-aggregates. Those of ordinary skill in the art are familiar with two-dimensional J-aggregates. A two-dimensional J-aggregate has a very small thickness relative to its width and relative to its depth, resulting in a high aspect ratio between the width of the J-aggregate and the thickness of the J-aggregate (e.g., at least 100:1, at least 1000:1, at least 10,000:1, at least 100,000:1, or higher) and a high aspect ratio between the depth of the J-aggregate and the thickness of the J-aggregate (e.g., at least 100:1, at least 1000:1, at least 10,000:1, at least 100,000:1, or higher). In some embodiments, the light emitting material comprises a plurality of two-dimensional J-aggregates. For example, multiple two-dimensional J-aggregates may be encapsulated in a single coating material.

In some embodiments, a quantum yield of the light emitting material comprising a J-aggregate (e.g., a coated J-aggregate such as those described elsewhere herein, other devices incorporating the coated J-aggregates described herein, etc.) is high, which may be desirable for use in certain applications such as imaging, sensing, and/or quantum communication. Without wishing to be bound by any particular theory, the high quantum yields of the coated J-aggregates described herein may arise due to forming the coated J-aggregates by coating the J-aggregates in a manner that further purifies the J-aggregates during the coating process. It is believed this may reduce the number of impurities, and associated non-radiative decay pathways, advantageously leading to high quantum yields. It is further believed that the coating material, in some instances, may rigidify the J-aggregate structure, further limiting non-radiative decay pathways and increasing the quantum yield. In some embodiments, it is believed that the silica precursors provide a template for J-aggregate assembly, thereby forming J-aggregates with few-to-no lattice defects that can act as non-radiative recombination centers and resulting in higher quantum yields.

The quantum yield of light emitting material may be determined using the relative method, in accordance with certain embodiments. In such a relative method, the quantum yield of the J-aggregates may be calculated by using a rhodamine 6G standard with a known quantum yield. A series of solutions with different concentrations may be prepared by diluting a rhodamine 6G stock solution with methanol and comparing with a concentration series of the J-aggregate. Absorption and emission spectra of the standard and J-aggregate solutions may be collected, whereafter the integrated emission intensity may be plotted against the absorptance for each series, and the slopes of the calibration plots may be calculated. The quantum yield may then be calculated by incorporating the slopes from the calibration plots, refractive indices, and powers at different excitation wavelengths.

In some embodiments, the quantum yield of the light emitting materials described herein may be greater than or equal to 83%, greater than or equal to 84%, greater than or equal to 85%, greater than or equal to 86%, greater than or equal to 87%, greater than or equal to 88%, greater than or equal to 89%, greater than or equal to 90%, greater than or equal to 91%, greater than or equal to 92%, greater than or equal to 93%, greater than or equal to 94%, greater than or equal to 95%, greater than or equal to 96%, greater than or equal to 97%, greater than or equal to 98%, or greater than or equal to 99%. In some embodiments, the quantum yield of the light emitting materials described herein may be greater than or equal to 83%, greater than or equal to 84%, greater than or equal to 85%, greater than or equal to 86%, greater than or equal to 87%, greater than or equal to 88%, greater than or equal to 89%, greater than or equal to 90%, greater than or equal to 91%, greater than or equal to 92%, greater than or equal to 93%, greater than or equal to 94%, greater than or equal to 95%, greater than or equal to 96%, greater than or equal to 97%, greater than or equal to 98%, or greater than or equal to 99% at at least one temperature of from 20°° C. to 25° C. In some embodiments, the quantum yield of the light emitting materials described herein may be greater than or equal to 83%, greater than or equal to 84%, greater than or equal to 85%, greater than or equal to 86%, greater than or equal to 87%, greater than or equal to 88%, greater than or equal to 89%, greater than or equal to 90%, greater than or equal to 91%, greater than or equal to 92%, greater than or equal to 93%, greater than or equal to 94%, greater than or equal to 95%, greater than or equal to 96%, greater than or equal to 97%, greater than or equal to 98%, or greater than or equal to 99% at a temperature of 23° C. In accordance with some embodiments, the light emitting materials described herein may achieve a quantum yield within any of the foregoing ranges for at least one wavelength of emitted visible electromagnetic radiation. In the context of the present disclosure, visible electromagnetic radiation refers to electromagnetic radiation having a wavelength of greater than or equal to 380 nm and less than or equal to 750 nm. In some embodiments, the light emitting materials described herein may achieve a quantum yield within any of the foregoing ranges when excited with at least one wavelength of visible electromagnetic radiation. In some embodiments, the light emitting materials described herein may achieve a quantum yield within any of the foregoing ranges when excited with at least one wavelength of electromagnetic radiation within a range of 490 nm to 600 nm, or within a range of 500 nm to 565 nm.

In some embodiments, the emissive lifetime of the coated J-aggregate(s) and/or a light emitting material comprising the J-aggregate(s) is short, which may be desirable in certain applications such as quantum communication, sensing, and/or imaging. In accordance with certain embodiments, emissive lifetime (τ) is experimentally determined by exciting a population of J-aggregates with an excitation pulse and recording the fluorescence intensity decay. For a population of J-aggregates, the intensity decay follows an exponential decay model. For a mono exponential decay model: I₀=e^{-(t/τ)} where, t is the time from excitation, I₀ is the initial intensity, and τ is the time it takes the intensity to decrease to 1/e(=0.368) of its initial value. Accordingly, the emissive lifetime can be determined from the measured decay using the time it takes the initially emissive intensity to decrease to 1/e of its initial value, in accordance with some embodiments. In some embodiments, the intensity decay may be fitted with an exponential decay model to extract the lifetime. According to some embodiments, τ may be measured by taking the inverse of a decay constant for the function that best fits the emission decay. In some embodiments, the emissive lifetime of the coated J-aggregates and/or a light emitting material comprising coated J-aggregates may be less than or equal to 1 nanosecond, less than or equal to 750 picoseconds, less than or equal to 500 picoseconds, less than or equal to 400 picoseconds, less than or equal to 300 picoseconds, or less than or equal to 250 picoseconds. According to some embodiments, the emissive lifetime may be greater than or equal to 100 picoseconds. Combinations of the foregoing ranges are possible (e.g., greater than or equal to 100 picoseconds and less than or equal to 1 nanosecond). Other ranges are also possible. In some embodiments, the emissive lifetime of the coated J-aggregates and/or a light emitting material comprising coated J-aggregates may fall within any of the ranges outlined above at at least one temperature of from 20° C. to 25° C. In some embodiments, the emissive lifetime of the coated J-aggregates and/or a light emitting material comprising coated J-aggregates may fall within any of the ranges outlined above at a temperature of 23° C. In accordance with some embodiments, the light emitting materials described herein may achieve an emissive lifetime within any of the foregoing ranges for at least one wavelength of emitted visible electromagnetic radiation. In some embodiments, the light emitting materials described herein may achieve an emissive lifetime within any of the foregoing ranges when excited with at least one wavelength of visible electromagnetic radiation. In some embodiments, the light emitting materials described herein may achieve an emissive lifetime within any of the foregoing ranges when excited with at least one wavelength of electromagnetic radiation within a range of 490 nm to 600 nm, or within a range of 500 nm to 565 nm. In some embodiments, the J-aggregates described herein may have a small stokes shift when measured at 23° C. The stokes shift, in accordance with some embodiments, may be determined by measuring the peak absorption and the peak emission of the J-aggregate and determining the shift therebetween. According to some embodiments, the stokes shift of the J-aggregate may be less than or equal to 200 nm, less than or equal to 150 nm, less than or equal to 100 nm, less than or equal to 50 nm, less than or equal to 40 nm, less than or equal to 30 nm, less than or equal to 20 nm, less than or equal to 10 nm, less than or equal to 5 nm, or less than or equal to 2 nm.

In certain embodiments, the light emitting material comprises immobilized J-aggregates. In accordance with some embodiments, an immobilized J-aggregate may be immobile due to the presence of the coating.

As noted above, in some embodiments, the J-aggregate is coated with a coating material. In some embodiments, the J-aggregate is coated with silica, titania, hafnia, zirconia, and/or alumina. In certain embodiments, it can be particularly advantageous to coat the J-aggregate with silica. In some embodiments, the coating is conformal around the J-aggregate. In some embodiments, the coating may only partially coat the J-aggregate.

In some embodiments, the coating material of the J-aggregate may have a maximum thickness. In certain embodiments, the coating material (e.g., silica) has a maximum thickness of less than or equal to 10 nm, less than or equal to 8 nm, less than or equal to 6 nm, or less than or equal to 4 nm. In some embodiments, the maximum thickness of the coating is greater than or equal to 3 nm, greater than or equal to 4 nm, or greater than or equal to 6 nm. Combinations of the foregoing ranges are possible.

In some embodiments, the light emitting material comprises a plurality of J-aggregates coated with a coating material (e.g., silica), and an average maximum thickness of the coated J-aggregates is greater than or equal to 3 nm and less than or equal to 6 nm.

In certain embodiments, the light emitting material comprises J-aggregates comprising a plurality of aggregatable molecules. In certain embodiments, the light emitting material comprises J-aggregates comprising 5,5′,6,6′-tetrachloro-1,1′-diethyl-3,3′-di(4-sulfobutyl)-benzimidazolocarbocyanine (TDBC).

Typically, solutions containing J-aggregates additionally contain unaggregated molecular precursors (i.e., molecular precursors that are not associated with any other molecular precursors to form a J-aggregate). The presence of unaggregated molecular precursors may be determined by looking at the absorbance spectrum of the solution containing the J-aggregates, for example, by looking for absorbance peaks associated with the unaggregated molecular precursor. In some embodiments, the methods and compositions described herein yield solutions having relatively low amounts of non-aggregated molecular precursors. For instance, in some embodiments, the light emitting material comprises J-aggregates (e.g., comprising at least 10, at least 15, at least 20, at least 40, at least 60, at least 100, at least 200, or more aggregatable molecules), and no more than 20%, no more than 10%, no more than 5%, no more than 3%, no more than 2%, no more than 1%, or no more than 0.1% of the molecular precursors from which the J-aggregates were formed remain unaggregated. For example, in some embodiments, the light emitting material comprises at least 10 aggregatable molecules (i.e., molecular precursor to the J-aggregates), and fewer than 20% of the aggregatable molecules remain disassociated from another aggregatable molecule within the J-aggregate.

The following examples are intended to illustrate certain embodiments of the present invention, but do not exemplify the full scope of the invention.

### EXAMPLE 1

The following Example is generally related to light emitting materials having a high quantum yield and/or short emissive lifetime.

A two-step silica encapsulation procedure is described, resulting in high optical efficiency and structural robustness of 5,5′,6,6′-tetrachloro-1,1′-diethyl-3,3′-di(4-sulfobutyl)-benzimidazolocarbocyanine (TDBC), a two-dimensional sheet-like J-aggregate. The fluorescence quantum yield was approximately 98%, the highest quantum yield recorded for any J-aggregate structure at room temperature, and having a fast, emissive lifetime of 234 picoseconds. Silica, as an encapsulating matrix, provides optical transparency, chemical inertness, and robustness to dilution, while rigidifying the J-aggregate structure. The in situ encapsulation process described in this Example preserves the excitonic structure in TDBC J-aggregates, maintaining their light absorption and emission properties. The homogeneous silica coating has an average thickness of 0.5-1 nm around J-aggregate sheets. Silica-encapsulation permits extensive dilutions of J-aggregates without significant disintegration of the J-aggregates into the constituent aggregatable molecules (e.g., monomers of the J-aggregate). The J-aggregates exhibited narrow absorbance and emission line widths at room temperature (e.g., 23° C., 296 K), and exhibit further narrowing upon cooling to 79 K, which is consistent with J-type coupling in the encapsulated aggregates. The silica encapsulated TDBC J-aggregate construct of this Example signifies (1) a new bright, fast, and robust fluorophore system, (2) a platform for the further manipulation of J-aggregates as building blocks for integration with other optical materials and structures, and (3) a system for the fundamental studies of exciton delocalization, transport, and emission dynamics within a rigid matrix.

J-aggregates, supramolecular assemblies of organic molecules exhibiting unique optical properties, are interesting fluorophores because of their exceptional color purity and fast emissive lifetimes. These aggregates typically form through the self-assembly of x-conjugated chromophores, resulting in structures with distinct spectral shifts and enhanced light-harvesting capabilities. After the initial discovery of J-aggregates, supramolecular assemblies of cyanine dyes have garnered interest due to their unique exciton properties, which are distinct from the behavior of their constituent dye aggregatable molecules. In some cases, J-aggregates exhibit a remarkable level of organization with an array of morphologies, including fibers, sheets, tapes, ribbons and nanotubes. The close alignment of chromophores within J-aggregates results in strong electronic state interactions, leading to supramolecular excitons spanning across multiple aggregatable molecules. Superradiance occurs when the ensemble of aggregated molecules collectively emits light coherently. This cooperative emission may cause redshifted and narrowed spectra, extended exciton delocalization, long-range exciton transport, and notably sub-nanosecond emissive lifetimes. Leveraging these exceptionally unique properties, the light emitting materials comprising J-aggregates described in this example may be used in sensing and imaging applications, and they may be bright, fast, and ideal light sources for high-speed free-space optical and quantum communication. Previously, J-aggregates suffered from limitations that hindered their use in devices and other applications. These limitations included low structural stability and low photoluminescence quantum yields (QYs). To address these limitations, in this Example, a method that generates a bright and fast, sheet-like J-aggregate fluorophore, characterized by substantially improved structural robustness and close to unity QY, is described.

Silica encapsulation (e.g., coating the J-aggregates with silica), with its well-established versatility and stability, was hypothesized to provide a protective and tunable environment for J-aggregates. Silica was hypothesized to act as an ideal encapsulating matrix for J-aggregates due to its optical transparency, chemical inertness, and ease of functionalization. The integration of J-aggregates into silica matrices as described in this Example introduces a synergy, combining the distinctive characteristics of J-aggregates with the structural benefits of a silica host. This encapsulation strategy not only shields J-aggregates from external influences but also offers a platform for tailoring their optical properties, mechanical stability, and surface modifications while preserving their J-aggregate morphology and inherent optical properties.

Previously, silica-encapsulation of tubular C8S3 J-aggregates has been performed and resulted in increased chemical and mechanical stability due to successful homogeneous and uniform silica-encapsulation. These silica-stiffened C8S3 J-aggregates exhibited chemical stability against changes in pH in the medium and mechanical stability against drying. However, these tubular, silica-encapsulated J-aggregates exhibited a low photoluminescence QY of 8%.

In this Example, the enhancement of the structural robustness and optical efficiency of two-dimensional sheet-like 5,5′,6,6′-tetrachloro-1,1′-diethyl-3,3′-di(4-sulfobutyl)-benzimidazolocarbocyanine, commonly known as TDBC J-aggregates, was explored. TDBC dye molecules are known to self-assemble into 2D sheets spanning several hundred nanometers in water-methanol blends. These J-aggregates exhibit distinctive optical features from their constituent dye molecules, including extremely narrow absorption and emission spectra, rapid radiative rates, extensive exciton delocalization and excitation migration. Previously, the reported QYs for TDBC J-aggregates in solution were unsatisfactory, ranging from 5 to 49%, thus limiting their use in optical applications. However, we recently demonstrated a QY of 82% with a 174 ps emissive lifetime through the purification of monomers prior to their self-assembly. Purification of monomers as described herein facilitates removal of impurities embedded in the densely packed J-aggregate supramolecular lattice. Without removal, the impurities may trap excitons and function as non-radiative recombination centers (e.g., decreasing quantum yield). While the optical performance of TDBC J-aggregates has improved, their persistent structural and chemical instability restricts their practical applications. This limitation also leaves room for further enhancement of their optical properties, including their fluorescence QY. To address this constraint, in this Example, methods to immobilize TDBC J-aggregates within a silica matrix using a two-step method that further increases the fluorescence QY are disclosed.

This example describes a novel protocol for the silica-encapsulation of TDBC J-aggregate sheets using two silica precursors, namely, (3-aminopropyl) triethoxysilane and tetraethyl orthosilicate, in the presence of aqueous ammonia. The absorption and emission spectra of the silica encapsulated J-aggregates exhibited no significant changes relative to the bare (e.g., non-encapsulated) J-aggregates, indicating that silica encapsulation has no effect on the existing excitonic structure or morphology of the TDBC J-aggregates. Microscopic analysis, including cryo-TEM images and scanning transmission electron microscopy with energy dispersive X-Ray analysis, confirmed a successful and homogeneous silica coating on the J-aggregate sheets. Dynamic light scattering revealed a smaller lateral size for silica-coated J-aggregates than for bare J-aggregates. Stability studies involving dilution of the J-aggregates demonstrated that the enhanced structural integrity provided by silica coating helps to maintain the integrity of the J-aggregates, facilitating extensive dilutions without disassociation of the J-aggregates into constituent aggregatable molecules. In this Example, a QY of 98% for TDBC J-aggregates was achieved, the highest recorded for any J-aggregate, through silica-encapsulation. The measured emissive lifetime of the J-aggregate was 234 ps. This Example demonstrates a significant improvement of light emitting molecules, e.g., comprising J-aggregates as building block emissive materials, exhibiting a photoluminescence QY that is essentially unity at room temperature, reaching the limits of a bright, fast, and robust ideal fluorophore with enhanced processability.

### Results and Discussion

In Situ Two-Step Silica-Encapsulation Procedure and Characterization of TDBC J-Aggregates

The chemical structure of TDBC comprises a benzimidazole core with tetrachloro substituents, connected through a delocalized trimethine chain. Owing to the presence of the two sulfobutyl groups, the molecule shows a distinctive amphiphilic nature. The amphiphilic character arises from the coexistence of the hydrophilic sulfobutyl and hydrophobic tetrachloro-benzimidazole components within the same dye molecule. It imparts the ability for the molecule to interact with both polar and non-polar environments, facilitating its solubility in aqueous solutions while maintaining its compatibility with the organic phase. Previous studies have reported polymer coatings on J-aggregates utilizing such electrostatic interactions. The two-step silica-encapsulation procedure shown in FIG. 1A, uses the amphiphilicity of TDBC dye monomers to encapsulate TDBC sheet-like J-aggregates in amorphous silica.

The procedure described in the Example is based on the sequential addition of amine-functionalized silane, (3-aminopropyl) triethoxysilane (APTES) and tetraethyl orthosilicate (TEOS). In contrast to previous methods, during step-1 (FIG. 1A), in the presence of APTES, monomers undergo self-assembly. At first, due to the high affinity of the monomers (e.g., aggregatable molecules) to amines, TDBC readily dissolved in APTES, creating monomer-rich regions, and eventually form two-dimensional sheet-like TDBC J-aggregates in the ultrapure water, resulting in a pink-colored homogeneous solution. Upon hydrolysis, APTES becomes adsorbed onto the negatively charged sulfonate groups projecting from both the top and bottom sides of the J-aggregate sheets through electrostatic interactions. Ideally APTES forms a monolayer, strategically covering the surface of TDBC sheets and acting as an anchoring group for the second silica precursor, TEOS, introduced in step-2 (FIG. 1A). TEOS contributes to the growth of the silica shell and by varying the TEOS concentration, the shell thickness can be controlled. The addition of aqueous ammonia in step-2 served a dual purpose: (i) It catalyzed the hydrolysis of silica precursors (APTES and TEOS) and triggered the cross-linking of silanes, resulting in the loss of ethane groups such as ethanol and the subsequent formation of silica, and (ii) the role of ammonium extends beyond base catalysis as it also serves to shield the silica coated J-aggregates from further aggregation and thus limited the physical size of the J-aggregates.

The absorption (FIGS. 1B, 1H-1I) and emission (FIGS. 1C, 1H-1I) spectra of the silica-encapsulated TDBC J-aggregates are nearly identical to those of the bare J-aggregate solutions. The consistent peak positions show that the excitonic structure of pristine J-aggregates remains unaffected by silica-encapsulation. When the normalized absorption and emission spectra of the bare and silica-encapsulated TDBC J-aggregates overlap (FIGS. 1H-1I), a very small red shift of less than 1 nm is observed. Upon silica-encapsulation, C8S3 tubular J-aggregates also exhibit a small red shift in the peak at 599 nm. Slight structural distortions introduced by the adsorption of the silica precursors APTES and TEOS onto J-aggregate sheets or solvatochromic effects are assumed to cause this slight shift.

Cryo-TEM images (FIGS. 1E, 1F) show two-dimensional sheet-like morphologies for silica-encapsulated J-aggregates that are similar to those for bare J-aggregates but with greater abundance and smaller sizes. In the presence of silica precursors and aqueous ammonia, encapsulated J-aggregates are only several hundreds of nanometers in size, in contrast to the bare J-aggregates, which span more than a micron. The greater contrast observed for silica-encapsulated J-aggregates, due to the higher electron density caused by the silica sheath, provides a clear indication of a homogeneous silica coating on the surfaces of the J-aggregate sheets. Dynamic light scattering (DLS) autocorrelation curves (FIG. 1D) and normalized intensity distribution plots (FIG. 1J) show a comparatively smaller size for silica-encapsulated J-aggregates, supporting Cryo-TEM observations. FIG. 1J shows a DLS size distribution obtained for the bare and silica encapsulated J-aggregates. DLS measures the variations in light intensity due to the movements of macromolecules in the solution. The autocorrelation function reported in FIG. 1D represents the speed at which the intensity fluctuates over time. By analyzing the intensity autocorrelation plot, the translational diffusion coefficient (D) can be derived. The hydrodynamic radius (Rh) of the J-aggregate colloidal particles can then be calculated using D and the Stokes-Einstein equation. However, the colloidal particles are assumed to take a spherical morphology when calculating the Rh. DLS data for bare and silica-encapsulated TDBC J-aggregates revealed that silica-coated J-aggregates were smaller in size, supporting the observations from the Cryo-TEM images (FIG. 1F).

Monomeric TDBC was purified and dissolved in methanol as described in the methods section, and the solution showed an orange color in the solution (FIG. 1G-left). An aliquot of dissolved monomers was added to a water/methanol mixture (12:1 v/v) to spontaneously form the J-aggregates (FIG. 1G-middle), resulting in a pink solution. Once the two-step silica-encapsulation procedure is complete, bright pink silica-encapsulated J-aggregates (FIG. 1G-right) were formed. The increase in the intensity of the absorption and emission spectra of the silica-encapsulated TDBC J-aggregate sample in comparison to the bare J-aggregate sample, both of which were prepared from the same monomer dye concentration of 0.15 mM, indicates a boost in the formation of J-aggregates in the presence of silica precursors. The absorption spectrum for bare J-aggregates shows a small peak around 517 nm, corresponding to the presence of non-aggregated TDBC monomers. This monomer peak is essentially nonexistent for silica coated J-aggregates, further confirming the increased growth of J-aggregates in the presence of silica precursors. As shown in FIG. 1A, self-assembly of TDBC monomers into J-aggregate sheets occurred in the presence of APTES. The electrostatically adsorbed cationic APTES promotes seeding and self-assembly by attracting free monomers through their sulfonate groups. The addition of ammonium during the second step prevents the agglomeration of silica encapsulated J-aggregate sheets.

### Surface Analysis of Silica-Encapsulated TDBC J-Aggregate Sheets

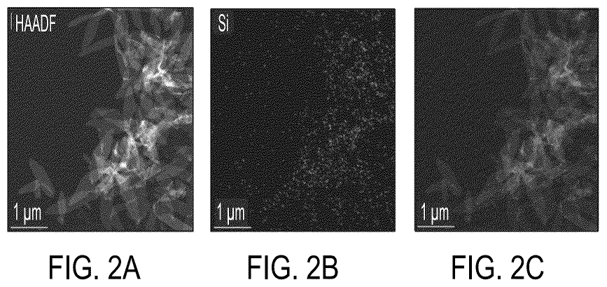

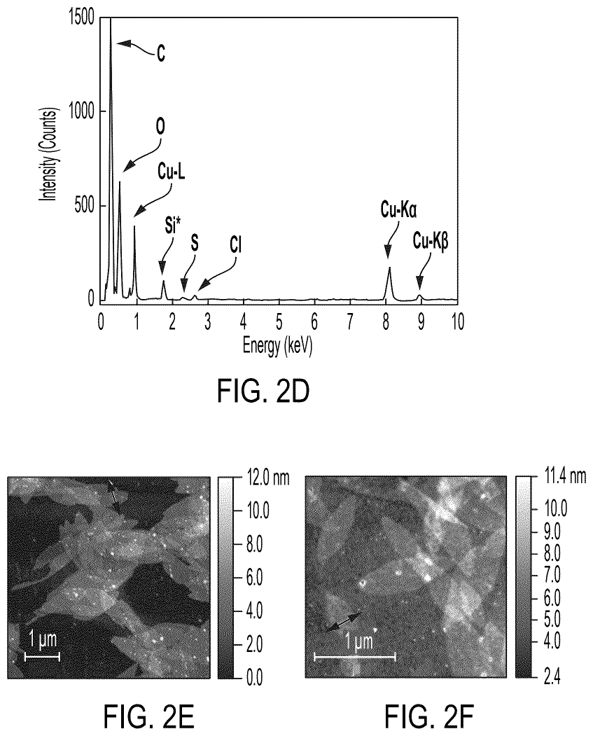

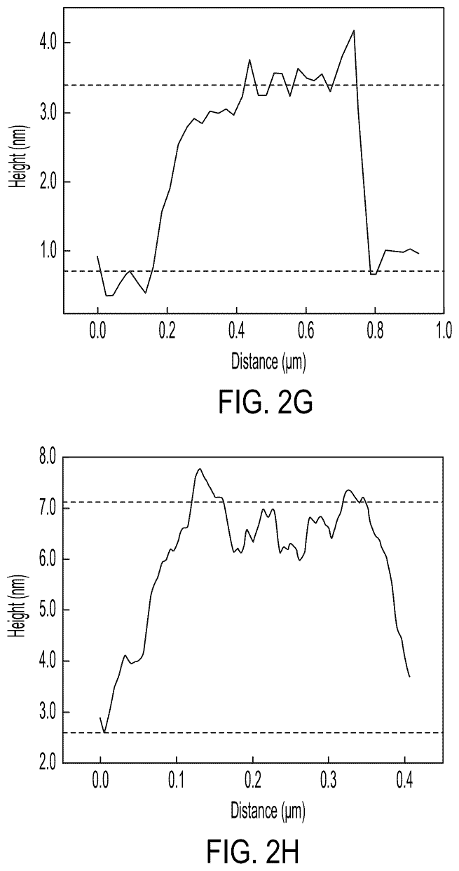

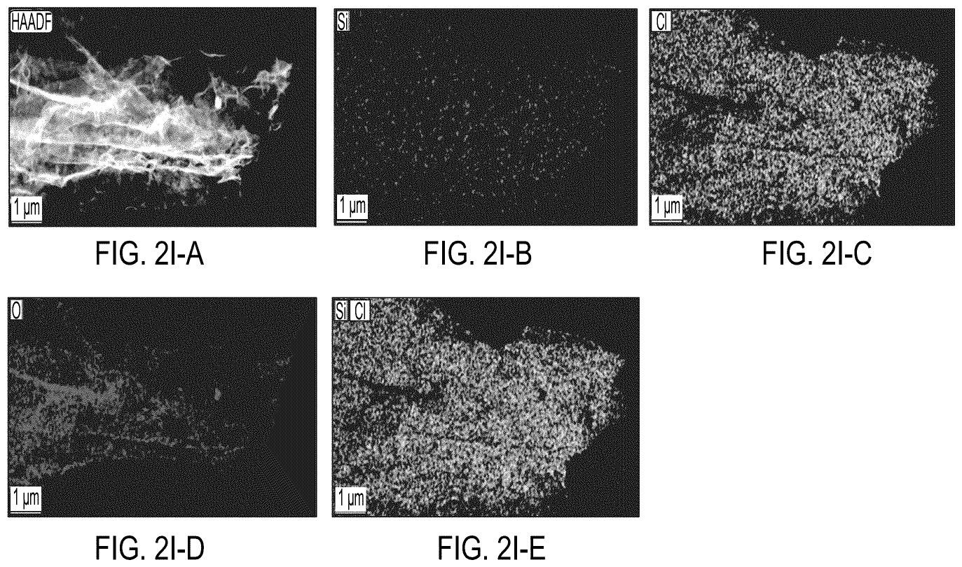

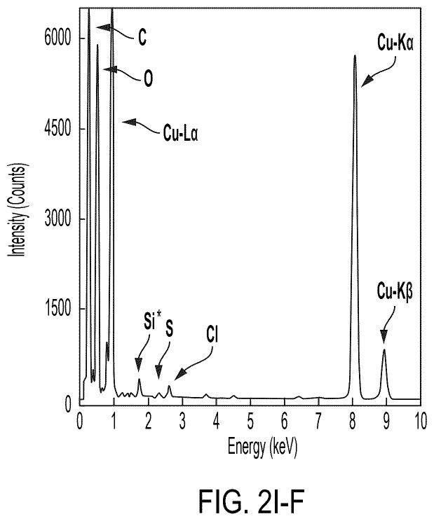

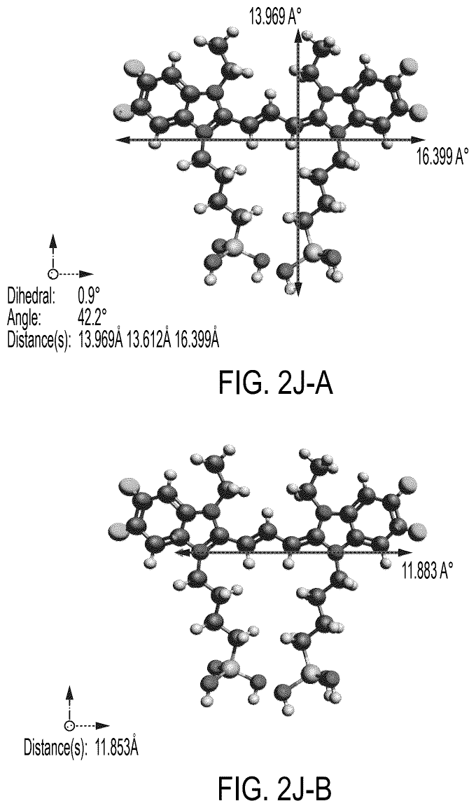

Silica-encapsulation preserves the excitonic structure and existing optical properties of bare J-aggregates while providing them with a protective and chemically tunable surface. Successful encapsulation should be homogeneous and should substantially cover both the top and bottom surfaces of the J-aggregate sheets. FIGS. 2A-2H shows chemical, surface, and thickness analyses of silica-encapsulated and bare TDBC J-aggregates. The chemical composition of the silica-encapsulated TDBC J-aggregates was characterized using scanning transmission electron microscopy (STEM). STEM images are consistent with the elliptical shape of the silica-encapsulated TDBC J-aggregates observed via cryo-TEM. FIG. 2A shows a high-angle annular dark-field (HAADF)-STEM image, and FIGS. 2B, 2C show energy dispersive X-ray (EDX) elemental maps of silicon in the same field of view and an overlap of the silicon distribution map with the HAADF-STEM image, respectively. FIG. 2D presents an integral EDX spectrum showing silicon (Si) and oxygen (O) from silica-encapsulation and sulfur (S) and chlorine (Cl) from TDBC.

Elemental mapping of silicon along with the overlap of HAADF-STEM images is consistent with homogeneous silica growth on the surfaces of TDBC J-aggregate sheets, as the denser distribution of silicon considerably overlaps with the J-aggregate region (FIGS. 2B, 2C).

The mechanical stability of the silica-encapsulated J-aggregates increased as shown in FIG. 2A; drying in air did not damage or disturb the sheet morphology. STEM-EDX analysis of silica-encapsulated TDBC J-aggregate sheets that were drop cast and dried on a hot plate confirmed homogeneous silica-encapsulation but had a distorted shape (FIG. 21).

FIG. 2I shows STEM-EDX analysis of silica-encapsulated TDBC J-aggregates, which were drop-cast on TEM grids and dried on a hot plate, confirms the homogeneous silica encapsulation of the J-aggregate sheets. However, J-aggregates are sensitive to temperature differences, and upon heating, the 2D sheets further stack on each other, aggregate, and distort, as shown in FIG. 2I-A. Since the monomer consists of four peripheral chlorine atoms, the elemental map of chlorine outlines the J-aggregate surface. The denser oxygen map in FIG. 2I-D is due to the oxygen present in both the J-aggregate monomers and the formed silica shell. The significant overlap observed between the elemental mapping of Si and Cl in FIG. 2I-E confirms homogeneous silica growth on the J-aggregate surfaces.

Atomic force microscopy (AFM) studies of bare and silica-encapsulated TDBC J-aggregate sheets and the resulting surface topography images are presented in FIG. 2E and 2F, respectively. Some sheets tend to stack, fold and overlap upon drying and adsorption onto the silica substrate, creating regions rich in J-aggregates. An analysis of the height profile of a bare J-aggregate sheet reveals an average thickness of approximately 2.7 nm (FIG. 2G), while that of a silica-encapsulated J-aggregate sheet is approximately 4.5 nm. Consequently, an additional thickness of ˜2 nm silica is added to the sheet.

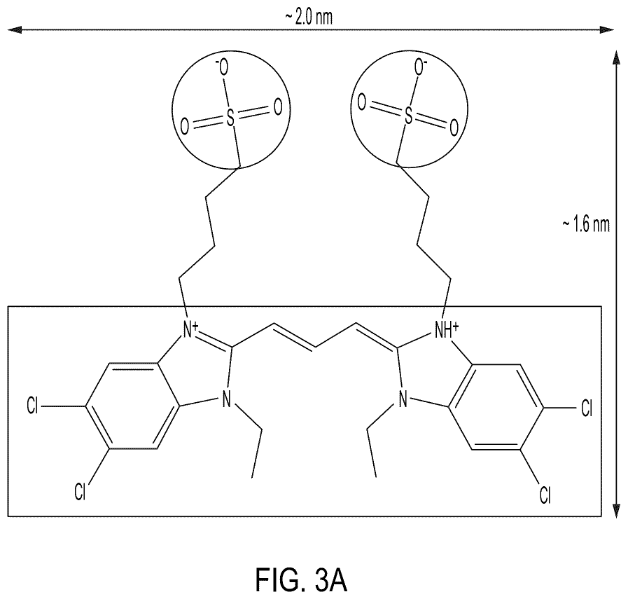

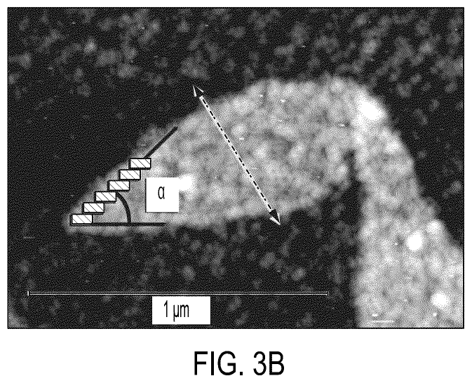

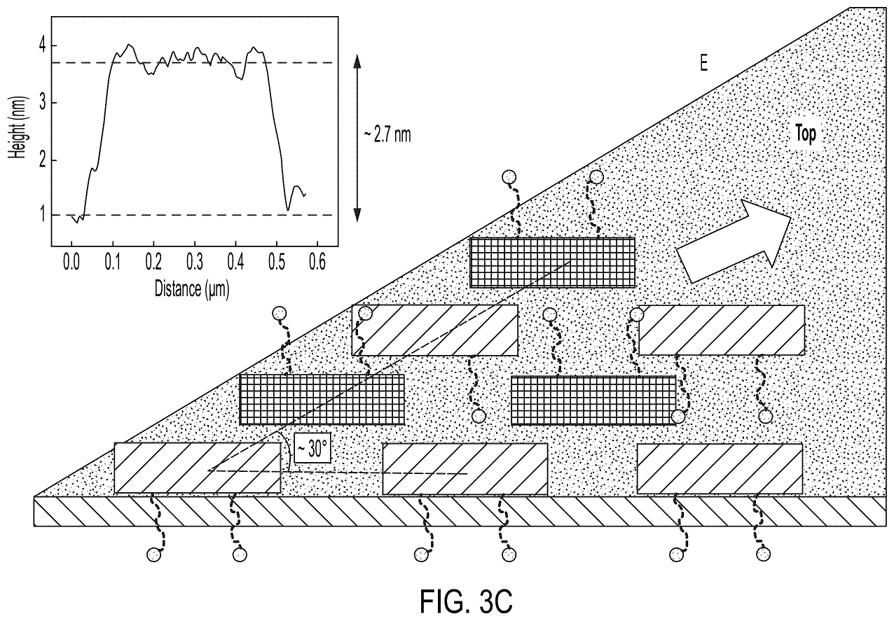

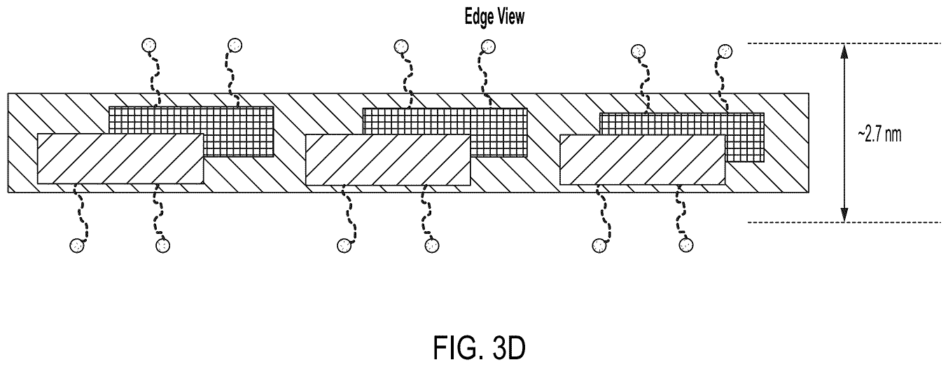

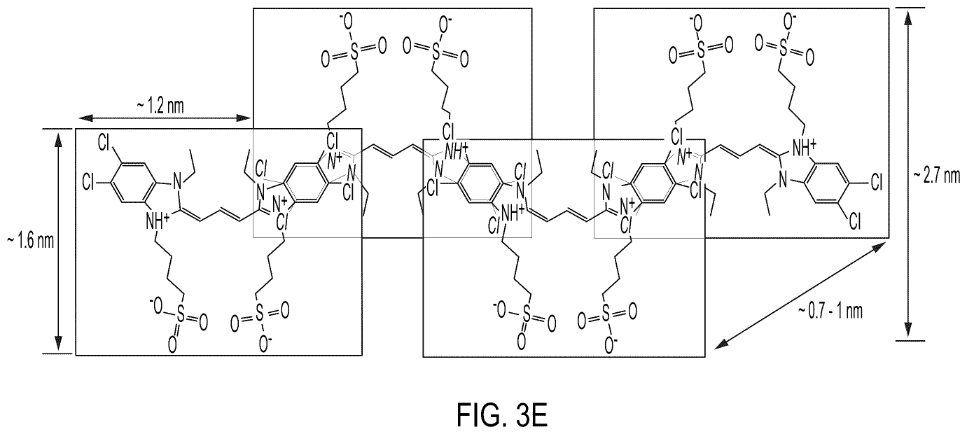

The AFM height profile of the bare TDBC J-aggregate sheets aids in determining the molecular stacking geometry within the TDBC J-aggregate sheets. The three basic monomer arrangements in J-aggregates include staircase, ladder, and brickwork geometries. The probable molecular geometry of the two-dimensional TDBC J-aggregate sheets is identified as the staircase arrangement, with molecular planes oriented normally to and along the long axis of the supramolecular lattice structure. When the monomers are stacked in the anti-parallel directions with a vertical molecular orientation, the efficient overlap of delocalized π-electron clouds is achieved through a slight lateral displacement of adjacent molecules, known as slippage (S). This non-zero slippage generates a slip angle (α), α=atan(D/S), where D represents the distance between two adjacent monomer planes. According to the Avogadro Molecule Editor and Visualizer (FIG. 2J), the height of a TDBC dye molecule is approximately 1.6 nm (FIG. 3A) while AFM reveals that the thickness of a bare J-aggregate sheet is approximately 2.7 nm (FIG. 3B and 3C). Therefore, to agree with this height difference, the TDBC molecules must be in a vertical, anti-parallel, slightly staggered and non-linear arrangement, as shown in edge view (FIG. 3D). The long axes of the TDBC monomers are aligned parallel to each other and to the long axis of the J-aggregates, while the monomer planes are arranged perpendicular to the plane of the sheet (FIG. 3E). The bilaterally exposed polar sulfobutyl chains contribute to stabilizing the self-assembled structure in the aqueous medium while enabling silica encapsulation from both the top and bottom sides of the sheets. A clearer representation of the monomer arrangement is given in FIG. 3E. As sulfonate groups extend from either side of the J-aggregate sheet, APTES is adsorbed on both sides, facilitating the formation of a silica sheath around the two-dimensional lattice and effectively protecting the J-aggregates from the external environment. The experimental data confirm the formation of an approximately 1 nm thick silica coating. The slip angle is measured by considering the acute angle at the vertices of TDBC sheets observed through AFM topography images. The average slip angle is approximately 30-40 degrees for bare TDBC J-aggregate sheets. Using Avogadro structural analysis, the slippage of adjacent monomers, (S), was measured to be approximately 1.2 nm (FIG. 2J), resulting in an inter-monomer spacing (D) of ˜ 0.7-1.0 nm.

### Structural Stability and Optical Enhancement Through Silica-Encapsulation

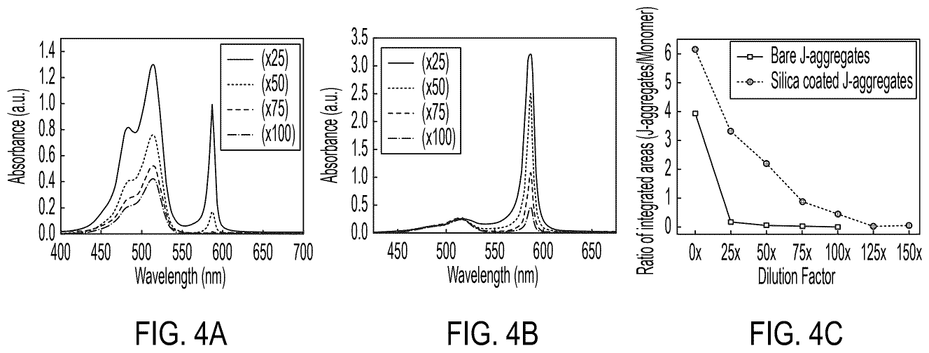

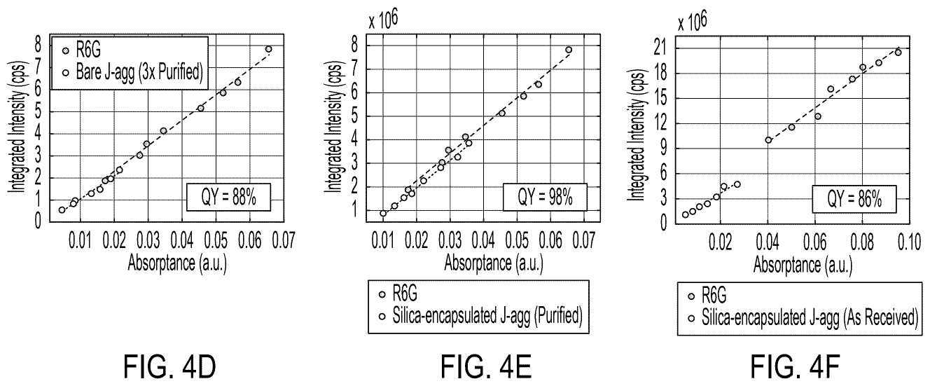

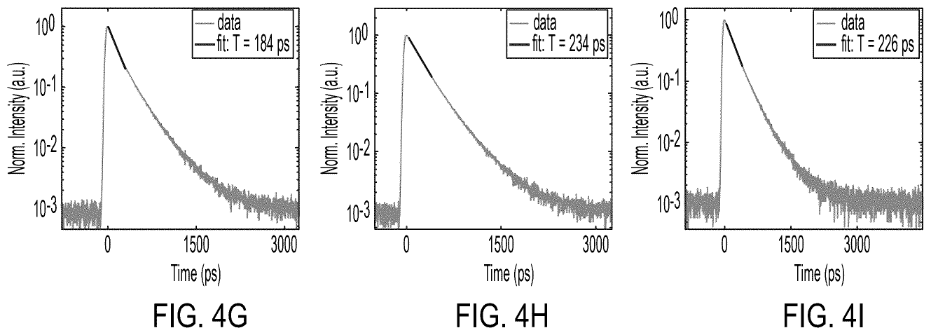

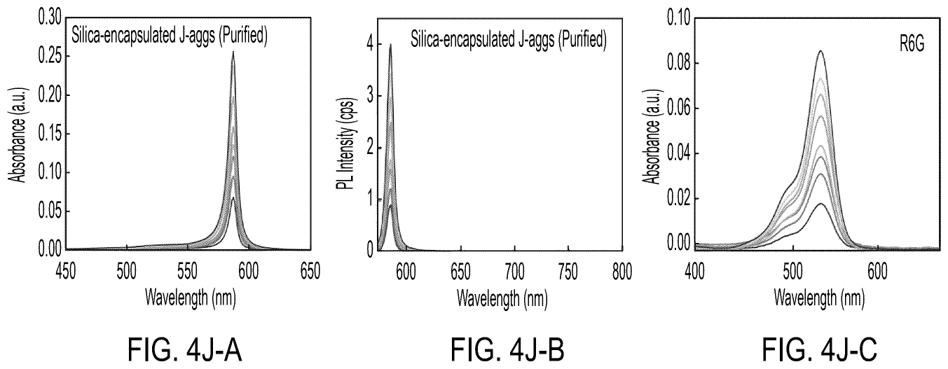

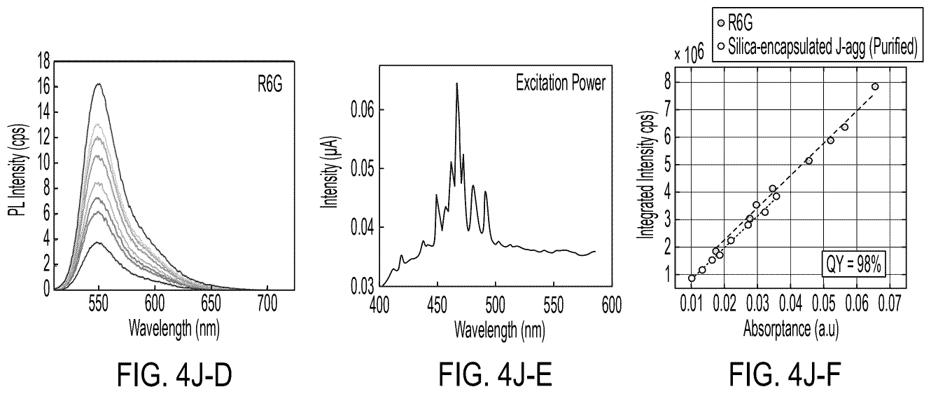

The formation of a silica sheath, covering the entire J-aggregate, effectively shields it from external environmental stresses. This protective mechanism was experimentally verified through extensive dilution of stock solutions of bare (FIG. 4A) and silica-encapsulated (FIG. 4B) J-aggregates in ultrapure water. During the dilution process, ultrapure water was carefully added to the J-aggregate stock solution, ensuring that the assembly of the already formed J-aggregates remained undisturbed. The J-aggregate/monomer ratio, obtained from the integrated absorption spectra (areas corresponding to 400-550 nm for the monomer and 551-650 nm for the J-aggregates), was plotted as a function of the dilution factor for both the bare and silica-encapsulated J-aggregates (FIG. 4C). Notably, a sharp decrease in the J-aggregate/monomer ratio for bare J-aggregates at a 25-fold dilution underscores the structural fragility of bare-J-aggregates. The mechanical stress induced by dilution prompts the ready disassembly of bare J-aggregates into their monomers, as indicated by the prominent absorption peak at 517 nm in FIG. 4A, corresponding to TDBC monomers. In contrast, silica-encapsulated J-aggregates exhibit increased robustness, retaining structural integrity without substantial disintegration even at a 125-fold dilution. This robustness resulting from silica encapsulation ensures the structural stability of the TDBC J-aggregates under extensive dilution.

The photoluminescence QY of TDBC J-aggregates was measured using the reference method with a solution of rhodamine 6G in methanol (QY of 93%) as the standard. The detailed QY calculation is given in FIG. 4J. QY (silica-encapsulated TDBC

$$J - aggregates ) = \frac{1.16 \cdot {10}^{8}}{1.15 \cdot {10}^{8}} \cdot {( \frac{1.333}{1.329} )}^{2} \cdot \frac{0.0372}{0.0358} \cdot 93 \% = 98 \% ,$$

where the ratios represent the slopes of the calibration plots, refractive indices of water and methanol, and powers of excitation at 500 nm for rhodamine 6G and at 565 nm for the silica-encapsulated TDBC J-aggregates, respectively.

TDBC J-aggregates were formed from monomers that were purified prior to their self-assembly. The QY enhancement was achieved by removing impurity sites that act as non-radiative recombination centers. Increasing the number of purification steps to three did not result in a substantial improvement in the QY of bare J-aggregates, moving from 82% to 88% (FIG. 4D). The QY for silica-encapsulated TDBC J-aggregates from purified monomers was, in turn, 98% (FIG. 4E). As a control experiment, the same experiment was conducted for silica-encapsulated TDBC J-aggregates formed without any prior monomer purification. Surprisingly, the photoluminescence QY of bare J-aggregates from monomers as received without any prior purification was enhanced from 56% to 86% by encapsulation alone (FIG. 4F) showing that the silica-encapsulation process itself optically enhances TDBC J-aggregates without the essential need for monomer purification.

Without wishing to be bound by any particulate theory, it is believed that the enhancement in QY through silica-encapsulation can be explained by three factors. (I) APTES plays a dual role as a silica precursor and a primary amine, concentrating monomers before self-assembly and, as reported previously, enhances the QY by an order of magnitude. As illustrated in FIG. 1A, the silica-encapsulation procedure of this Example, in contrast to previously reported methods, involves the formation of J-aggregates in the presence of APTES by first concentrating the monomers in the APTES phase. The non-aggregated monomeric form of TDBC is soluble in the amine phase, but due to its amphiphilic nature, J-aggregation occurs along the water-amine interface. Additionally, any monomers loosely bound to J-aggregates, potentially causing faulty stacking or defects, are expected to dissolve in the amine phase, allowing pristine J-aggregate growth. (II) Silica precursors promote defect-free molecular packing in a similar way that previous works introduce small molecules and surfactants to promotes defect-free close packing of monomers, which results in an increase of the QY. In this Example, as J-aggregates self-assemble, supramolecular lattice voids are filled by electrostatically adsorbing APTES, thus promoting dense molecular packing within the J-aggregates and strong coupling between chromophores. (III) Silica encapsulation leads to the formation of smaller J-aggregate sheets. This reduction in physical size is attributed to the self-assembly of J-aggregates in the water-APTES bi-continuous phase, the mechanical disturbance induced by silica mineralization, and the controlled growth of J-aggregates in the presence of ammonium. The controlled size of the J-aggregates limits the availability of non-radiative recombination sites, thereby enhancing radiative recombination and the photoluminescence QY. Collectively, these three factors explain the near-unity QYs observed in our silica-encapsulated J-aggregates. Furthermore, the high QY observed for silica-encapsulated J-aggregates from unpurified monomers may be attributed to in situ purification of monomers at the water-APTES bi-continuous interface during self-assembly.

The time-resolved fluorescence decay of bare J-aggregates from purified monomers follows a mono-exponential curve with a lifetime of 184 ps (FIG. 4G). This is slightly longer than the 174 ps emission lifetime earlier reported for J-aggregates formed from one-time purified monomers. Silica-encapsulated J-aggregates from both purified and unpurified monomers display emissive lifetimes of 234 ps and 226 ps, respectively. Using the QY and emissive lifetime data, we calculate the radiative and non-radiative rates for bare and silica-encapsulated J-aggregates, with and without prior monomer purification, as tabulated below (Table 1).

TABLE 1
QY, emissive lifetime, radiative and non-radiative rates for bare TDBC J-aggregates
formed from monomers as received and purified and for silica-encapsulated
TDBC J-aggregates formed from monomers as received and purified.

| | Quantum | Emissive | Radiative | Non-radiative |
|---|---|---|---|---|
| | Yield | Lifetime | Rate | Rate |
| TDBC J-aggregate Type | (ϕ) | (τ) | (k_{rad}) | (k_{non-rad}) |
| Bare J-aggregates without | 56% | 167 ps | 3.4 · 10⁹ s⁻¹ | 2.6 · 10⁹ s⁻¹ |
| monomer purification | | | | |
| Bare J-aggregates with | 88% | 184 ps | 4.8 · 10⁹ s⁻¹ | 6.5 · 10⁸ s⁻¹ |
| monomer purification | | | | |
| Silica-encapsulated J- | 86% | 226 ps | 3.8 · 10⁹ s⁻¹ | 6.2 · 10⁸ s⁻¹ |
| aggregates without | | | | |
| monomer purification | | | | |
| Silica-encapsulated J- | 98% | 234 ps | 4.2 · 10⁹ s⁻¹ | 8.5 · 10⁷ s⁻¹ |
| aggregates with monomer | | | | |
| purification | | | | |

The radiative rate of TDBC J-aggregates formed from repetitively purified monomers was calculated to be approximately 1.4 times faster than the radiative rate of J-aggregates formed from monomers as received without any prior purification. The rates shown in Table 1 emphasize that both monomer purification and silica-encapsulation enhance the radiative rate, with monomer purification contributing the most. This is consistent with the growth of more pristine and coherent J-aggregates. Bare and silica-encapsulated J-aggregates, both with monomer purification, display higher radiative rates, confirming our previous hypothesis that a significant portion of the non-radiative decay in J-aggregates is due to impurity quenchers. Therefore, a combined approach in which monomers are initially purified before encapsulation to produce bright and fast emitters with unity QYs is suggested. The highest non-radiative rate is recorded for bare J-aggregates formed from unpurified monomers. Through the individual processes of purification and silica-encapsulation, this non-radiative rate is reduced by a factor of 4. However, the combined process of monomer purification and silica-encapsulation reduces the non-radiative rate by a factor of approximately 31.

### Temperature-Dependent Absorption and Emission Spectroscopy of Silica-Encapsulated TDBC J-Aggregates

A model to explain the type of coupling in one-dimensional molecular aggregates based on spectral shifts compared to their monomers was previously developed. The red or blue shift observed for molecular aggregates relative to their monomer peaks confirms negative or positive excitonic coupling in J- and H-type one-dimensional aggregates, respectively. However, the model cannot fully elucidate more complex excitonic behavior in two-dimensional aggregates, where the aggregate bright state could be lower in energy but still away from the band-edge, deviating from the J-aggregate nature, and referred to as I-aggregates. This behavior depends upon the relative slippage between neighboring monomers in the supramolecular assembly.

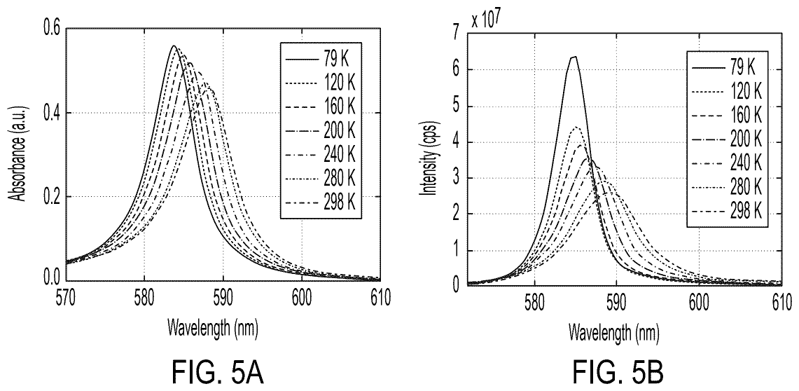

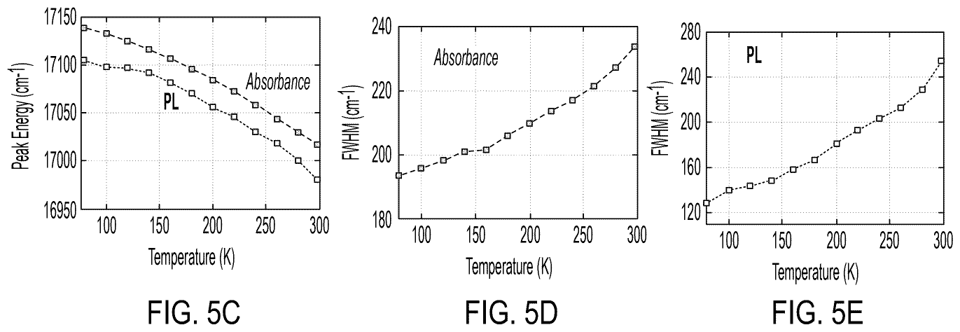

Temperature-dependent absorption and emission spectroscopy enables differentiation between J- and I-type coupling. In this study, as aggregates were formed in the presence of the primary silica precursor, APTES, it was important to verify the coupling type of the resulting silica-encapsulated TDBC J-aggregates. Therefore, silica-encapsulated TDBC J-aggregates were further characterized by stabilizing them in a sugar matrix, facilitating temperature dependent measurements. This method involves diluting the silica-encapsulated J-aggregates in a concentrated sucrose-trehalose solution (1:1 w/w %) and drying overnight under vacuum. The sugar matrix protects the J-aggregates from cryogenic damage and photobleaching and minimizes the re-absorption of J-aggregates. The sugar matrix-fixed silica-encapsulated J-aggregates continued to fluoresce even after being exposed to air and natural daylight for several days. The unaffected absorption and emission spectral features of the sugar matrix-fixed silica-encapsulated J-aggregates confirmed that the water removal process does not affect the structure or morphology of the J-aggregates. This method has been successfully employed in studying the temperature-dependent absorption and emission spectra of TDBC and Cy3UB J-aggregates. As the temperature decreases from 298 K to 79 K, both the absorbance and emission peaks exhibit a blue shift from 17,017 cm⁻¹ to 17,138 cm⁻¹ (from 587.7 nm to 583.5 nm) and 16,980 cm⁻¹ to 17,105 cm⁻¹ (from 589.0 nm to 584.6 nm), respectively (FIGS. 5A and 5B). The blue shift in the absorption and emission spectra is clearly illustrated by plotting the peak absorption and emission against temperature in FIG. 5C. An increase in the intensity of both the absorption and emission spectra upon cooling was observed. The absorbance and emission line widths show narrowing upon cooling, from 233.9 cm⁻¹ to 193.7 cm⁻¹ (8.1 nm to 6.6 nm) and from 254.8 cm⁻¹ to 128.8 cm⁻¹ (8.8 nm to 4.4 nm), respectively (FIGS. 5D and 5E). The absorption and emission peak positions and thermal broadening of silica-encapsulated TDBC J-aggregates red shift with increasing temperature. These observations are consistent with temperature-dependent spectroscopy of bare TDBC J-aggregates and consistent with J-type coupling between monomers.

### Conclusion

In this Example, the structural stability and optical efficiency of two-dimensional sheet-like TDBC J-aggregates was substantially improved by encapsulating them in silica. The silica precursors APTES and TEOS together form an amorphous silica shell covering both the top and bottom of the J-aggregate sheets protecting them from external stresses. APTES plays a dual role by acting both as a silica precursor and a primary amine. The self-assembly of J-aggregates in the presence of APTES aids in molecular level in situ purification of monomers, and provides a monomer enriched phase enabling defect-free pristine J-aggregate formation. Aqueous ammonia catalyzes the hydrolysis of silica precursors and limits further J-aggregate growth, resulting in smaller lateral sizes for silica-encapsulated J-aggregates, as visualized by cryo-TEM and confirmed by DLS. Additionally, silica-encapsulation provides a template for the assembly of TDBC monomers, encouraging further aggregation. Evidence for homogeneous silica coating on J-aggregate sheets was provided through STEM-EDX elemental mapping. Furthermore, the probable staircase monomer architecture for TDBC J-aggregate sheets was detailed by incorporating both AFM experimental data and molecular dimensions. According to the AFM height profiles, the thickness of the TDBC bare J-aggregate sheet is approximately 2.7 nm, and the successfully deposited silica coating had an average thickness of 0.5-1 nm. By varying the silica-precursor concentration, the shell thickness was controlled.

Silica-encapsulated J-aggregates survive up to 125-fold dilution in water, confirming the structural robustness of silica-encapsulation, paving the way for future spectroscopic investigations of isolated J-aggregates. Both purification and silica-encapsulation alone resulted in higher photoluminescence QYs. However, a near-unity photoluminescence QY of 98% is reported with a 234 ps emissive lifetime for silica-encapsulated TDBC J-aggregates formed from purified monomers. The combination of monomer purification and encapsulation results in J-aggregates with the lowest non-radiative rate, 8.5.107 s⁻¹, which is 31 times lower than that of bare J-aggregates formed from unpurified monomers. Finally, temperature-dependent absorption and emission spectroscopy studies on silica-encapsulated TDBC J-aggregates were presented to confirm the J-type coupling. Silica-encapsulation provides a platform for further surface functionalization of J-aggregates and integration with other optical materials. This approach provides a platform for fundamental studies of exciton delocalization, transport, and emission dynamics within a rigid matrix. Therefore, silica-encapsulated TDBC J-aggregates are a new building block fluorophore that is bright, fast, and robust.

### Methods

### Purification of TDBC Monomers

Unless otherwise noted, all J-aggregate samples were prepared using purified TDBC monomers. The procedure to purify the monomers was as follows. Initially, 150 mg of TDBC, as received from the vendor (FEW Chemicals, S0046), was dispersed in 25 mL methanol (>99.9%, VWR, EM-MX0488-1), and the resulting mixture was heated for 2 hours at 60° C. Afterwards, the mixture was slowly cooled to room temperature overnight in the dark. The supernatant was carefully removed without disturbing the suspension, and the solid was dried at 70° C., yielding 88 mg of the washed sample. This one-time washed sample was then dispersed again in 14 mL of methanol, and the purification step was repeated to yield 64.5 mg. During the third purification step, the solid from the second washing was dispersed in a 10 mL mixture of methanol and water (19:1, v/v), and the purification step was repeated. The dried, three-fold purified solid weighed 52 mg, resulting in a total yield of 35%.

### Preparation of Bare TDBC J-Aggregates

A 6.5 mL mixture of methanol and water (12:1, v/v) was added to a vial containing 3.2 mg of purified TDBC solid. After being covered with aluminum foil, the vial was heated at 60° C. for 1 hr to prepare 0.65 mM monomer stock solution. For the J-aggregate stock solution, 550 μL of ultrapure water (Milli-Ω, 18 MQ2 cm, Thermo Fisher Scientific) was added to 175 μL of the monomer stock solution in a cleaned vial. After gentle shaking and vortexing a few times a homogeneous pink-colored J-aggregate solution was obtained. J-aggregates from unpurified monomers were also prepared using the same procedure excluding the purification step. Unless otherwise specified, all the measurements were taken after equilibrating the solution overnight in the dark. To minimize J-aggregate exposure to light, the vials were wrapped in aluminum foil and stored in the dark.

Preparation of Silica-Encapsulated TDBC J-Aggregates

Silica-encapsulated J-aggregates were prepared inside a glove bag. APTES and TEOS were diluted in 1:49 v/v methanol solutions. In a cleaned vial, 10 μL of diluted APTES was added to 500 μL of ultrapure water and shaken well for several minutes to form an APTES-water solution blend. Subsequently, 175 μL of the TDBC monomer stock solution was added and vigorously shaken. Next, 10 μL of diluted TEOS and 10 μL of ultrapure water (to adjust the concentration) were added to the solution and mixed well. Afterwards, 20 μL of ammonium hydroxide was added, and the solution was mechanically shaken and vortexed at the maximum speed several times. The vial was then wrapped in aluminum foil, and the silica-encapsulated J-aggregate solution was kept in the dark overnight before any measurements were taken. Silica-encapsulated J-aggregates from unpurified monomers were prepared following the same procedure using the unpurified monomer stock.

### Absorption and Fluorescence Spectroscopy

Absorption and emission spectra were recorded using a Cary 5000 Spectrometer (Agilent) and FluoroMax Fluorometer (Horiba Scientific), respectively. Spectra were collected by depositing an appropriate volume (50-60 μL, with excess wiped off after deposition) of bare and silica-encapsulated J-aggregate stock solutions in demountable quartz cuvettes with 0.1 mm path length (Starna). Dilution studies were conducted by carefully diluting both the bare and silica-encapsulated J-aggregate stock solutions in ultrapure water. During the preparation of the dilution series, ultrapure water was slowly added along the vial wall to meet the J-aggregate stock solution at the surface without encouraging the disassembly of already formed J-aggregates. Absorption and emission measurements were taken after allowing the diluted solutions to equilibrate for approximately 4 hours. Temperature-dependent absorption and emission spectroscopy was performed on silica-encapsulated TDBC J-aggregates fixed in a sugar matrix. The saturated sugar solution was prepared by adding 1.5 mL of ultrapure water to a 2 g solid mixture of glucose (Sigma) and trehalose (Sigma) (1:1 w/w) and vigorously mixing by vortexing. A 100 μL aliquot of the silica-encapsulated TDBC J-aggregate stock solution was diluted by adding 100 μL of ultrapure water. After allowing the J-aggregate sample to equilibrate for 1 h, 200 μL of the sugar solution was slowly added to the diluted J-aggregate solution and mixed well to obtain a homogeneous solution. After 1 h, 60 μL of sugar matrix-fixed silica-encapsulated J-aggregate solution was deposited onto a 0.1 mm demountable quartz cuvette and dried under 0.5 atm vacuum for two nights. Once completely dry, the cuvette was covered with the top lid and placed in a cold finger cryostat (Janis Research Co., ST-100). The cryostat was evacuated using a turbo pump (Agilent, Varian 9698222) until the pressure decreased to ≤ 1.0×10⁻⁵ Torr. Initially, the sample was cooled under a constant flow of liquid nitrogen and the temperature was raised and controlled using a Lakeshore 330 Autotuning temperature controller.

The sample was equilibrated for 5 minutes at each temperature, and absorbance measurements were taken with excitation and emission slit widths set to 1 nm resolution. The temperature-dependent fluorescence spectra were collected using a home-built PL spectrometer with a silicon camera. The sample was excited using a 532 nm continuous diode laser (Thorlabs, CPS532). Sample photoluminescence was focused through the entrance of a monochromator (Teledyne Princeton Instrument, SP-3750), set with a 100 μm slit width (corresponding to approximately 0.5 nm PL spectral resolution), before striking a diffraction grating with a groove density of 50 g/mm and a blaze of 600 nm. Sample emission was then imaged using a thermoelectrically cooled silicon camera (Teledyne, PIXIS-100). The fluorescence measurements were obtained with a 100 ms camera exposure time and 10 exposures averaged per frame.

### Dynamic Light Scattering Measurements

A volume of 75 μL of ultrapure water was added to 225 μL of J-aggregate stock solution, and allowed to equilibrate for approximately 3 hours prior to DLS measurements. Correlograms for both bare and silica-encapsulated J-aggregates were collected using a Zetasizer Nano ZS90 (Malvern Instruments, Model: ZEN3690). The intensity distributions as a function of size for the bare and silica-encapsulated TDBC J-aggregates are given in FIG. 1J.

### Cryo-TEM Imaging

Instead of conventional TEM, cryo-TEM was employed to visualize bare and silica-encapsulated TDBC J-aggregates in their native environment. Copper grids covered with Quantifoil holey carbon support films (Q225CR-35, Quantifoil R 3.5/1, 200 mesh, Cu) were hydrophilized by glow discharge in an Emitech K100X Glow Discharger for one minute at 20mA. A volume of 3 μL of TDBC J-aggregate solution was applied onto a grid and blotted using a Vitrobot Mark IV (Thermo Fisher Scientific) to remove the excess solution, applying a blot force of 4 for 6 seconds. The blotted specimen was then flash-frozen by rapidly plunging it into liquid ethane at approximately −175 OC to vitrify the aqueous solution. Afterwards, under liquid nitrogen, the grids were transferred to the liquid nitrogen-cooled autoloader of Talos Arctica G2 Cryo-TEM (Thermo Fisher Scientific). To prevent J-aggregate degradation, imaging was performed under a minimal dose of the electron beam. The microscope was operated at an acceleration voltage of 200 kV with a 15 second exposure time, and the total exposure of the specimen was limited to 10.4 electrons/Å2. All images were collected at a magnification of 22,000X using a Falcon 3EC direct electron detector (Thermo Fisher Scientific) operated in linear mode. To generate sufficient contrast, images were collected in the −15 to −10 μm defocus range.

### Quantum Yield (QY)

The relative method was employed to calculate the QY of the TDBC J-aggregates. A methanol solution of rhodamine 6G (Sigma, 252433-250 MG), with a known QY of 93%, served as the standard. A series of solutions with different concentrations were prepared by diluting a rhodamine 6G stock solution with methanol. Similarly, another concentration series of J-aggregates was prepared by gently diluting the J-aggregate stock solution with water. The solutions were allowed to equilibrate for 3 hours before the measurements. The samples were deposited on 0.1 mm quartz cuvettes, and absorption and emission spectra were collected. For fluorescence emission spectra, rhodamine 6G and J-aggregates were excited at 500 nm and 565 nm, respectively. The integrated emission intensity was plotted against the absorptance for each series, and the slopes of the calibration plots were calculated. The QY was then calculated by incorporating the slopes from the calibration plots, refractive indices and powers at different excitation wavelengths. This procedure was repeated for both bare and silica-encapsulated J-aggregates, with and without prior monomer purification.

### Emissive Lifetime Measurements

Emissive lifetimes were measured for bare, silica-encapsulated J-aggregates formed from monomers with or without prior purification. The J-aggregate stock solution was gently diluted 30 times with ultrapure water and allowed to equilibrate for 3 hours before the emissive lifetime measurement. To maintain low optical density and minimize reabsorption, samples were prepared using capillary action in rectangular miniature hollow glass tubes (5012 Rectangle VitroTubes™) with a path length of 0.100 mm. Emission lifetime measurements were performed on a homebuilt microscope. The samples were excited with a wavelength-tunable ultrafast laser (Toptica Photonics FemtoFiber Pro) tuned to 565 nm with a repetition rate of 80 MHz and a power of 2 μW. The sample exposure during the measurements was kept brief to mitigate photobleaching. The laser was spectrally cleaned using Semrock VersaChrome edgepass filters and the light was focused on the sample using an achromatic doublet (80 mm focal length; Thorlabs AC254-080-A-ML) and collected with another 80 mm achromatic doublet. The excitation filter was a Semrock VersaChrome longpass filter. The light was then sent to a single-photon avalanche photodiode (Micro Photon Devices), and timing was performed with a PicoQuant Hydraharp 400 module. Steady-state spectra were collected on a Princeton Instruments Acton SP2500 and focused onto a Princeton Instruments ProEM CCD array. Lifetime traces were obtained by integrating the emission across the wavelength range of 570-600 nm over a minute. All the data were analyzed with custom software written in Matlab. STEM-EDX measurements

High-angle annular dark-field scanning transmission electron microscopy (HAADF-STEM) images and energy-dispersive X-ray spectroscopy (EDX) of silica-encapsulated J-aggregate sheets were collected using a Thermo Fisher Scientific Themis Z G3 STEM operating at an acceleration voltage of 200 kV, with a convergence angle of 19 mrad and 100 pA beam current. TEM grids with a Formvar film coated with a heavier layer of carbon (Carbon Type-B, 01813-F) on a copper 300-mesh support were used. Samples were prepared by drop casting 20 μL of the silica-encapsulated J-aggregate solution onto TEM grids without any additional dilution and were left to dry at room temperature for a couple of hours before imaging. AFM measurements

Atomic force microscopy (AFM) was carried out using a Cypher VRS1250 microscope operating in tapping mode in air with a fast-scanning, high-frequency silicon probe from Asylum Research Oxford Instruments (FS1500AUD, 1500 kHz, 6 Nm−1). The AFM images were processed, and the height profiles were analyzed using Gwyddion software. Substrates for AFM were prepared by spin-coating J-aggregate samples onto hydrophilized silica substrates at 1200 rpm for 2 minutes. The spin-coating procedure was repeated, and 5 μL of J-aggregate stock solution was added at a time until a sufficient amount of sample was deposited on the substrate. The silica shell thickness was determined by subtracting the average height of a bare-J-aggregate sheet from the height of a silica-encapsulated sheet and dividing by two.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein, “wt %” is an abbreviation of weight percentage. As used herein, “at %” is an abbreviation of atomic percentage. As used herein, “vol %” is an abbreviation of volumetric percentage. As used herein, “mol %” is an abbreviation of molar percentage.

Some embodiments may be embodied as a method, of which various examples have been described. The acts performed as part of the methods may be ordered in any suitable way. Accordingly, embodiments may be constructed in which acts are performed in an order different than illustrated, which may include different (e.g., more or less) acts than those that are described, and/or that may involve performing some acts simultaneously, even though the acts are shown as being performed sequentially in the embodiments specifically described above.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A light emitting material having a quantum yield of greater than or equal to 83% and an emissive lifetime of less than or equal to 1 nanosecond at at least one temperature of from 20° C. to 25° C.

2. A light emitting material, comprising:
a J-aggregate,
wherein a quantum yield of the J-aggregate is greater than or equal to 83% at at least one temperature of from 20° C. to 25° C.

3. The light emitting material of claim 2, wherein a quantum yield of the J-aggregate is greater than or equal to 96% at at least one temperature of from 20° C. to 25° C.

4. The light emitting material of claim 1, wherein the light emitting material comprises immobilized J-aggregates.

5. The light emitting material of claim 2, wherein the J-aggregate is coated with silica.

6. The light emitting material of claim 5, wherein the silica has a maximum thickness of less than or equal to 10 nm.

7. The light emitting material of claim 1, wherein the light emitting material comprises a plurality of J-aggregates coated with silica, and an average maximum thickness of the silica-coated J-aggregates is greater than or equal to 3 nm and less than or equal to 6 nm.

8. The light emitting material of claim 1, wherein the light emitting material comprises J-aggregates comprising 5,5′,6,6′-tetrachloro-1,1′-diethyl-3,3′-di(4-sulfobutyl)-benzimidazolocarbocyanine (TDBC).

9. The light emitting material of claim 2, wherein the light emitting material comprises at least 10 aggregatable molecules, and fewer than 20% of the aggregatable molecules remain disassociated from another aggregatable molecule within the J-aggregate.

10. The light emitting material of claim 2, wherein the J-aggregate is a two-dimensional (2D) J-aggregate.

11. A method, comprising:
establishing a solution comprising:
a molecular precursor of a J-aggregate, and
a molecule comprising a linker region and an initial coating material precursor;
allowing the J-aggregate to form in the solution;
mixing the solution and a secondary coating material precursor and a coating facilitator; and
allowing the J-aggregate to become coated in a layer comprising a coating material from the initial coating material precursor and the secondary coating material precursor.

12. A method, comprising:
establishing a solution comprising:
a molecular precursor of a J-aggregate; and
an amine-functionalized silane;
allowing the J-aggregate to form in the solution;
mixing the solution and an orthosilicate and ammonia; and
allowing the J-aggregate to become coated in a layer comprising silica.

13. The method of claim 12, wherein establishing the solution comprising the molecular precursor of the J-aggregate comprises dissolving the precursor in the amine-functionalized silane.

14. The method of claim 11, wherein allowing the J-aggregate to form in the solution comprises allowing the J-aggregate to form in the solution via self-assembly.

15. The method of claim 14, wherein during at least a portion of the self-assembly, amine-functionalized silane adsorbs to the J-aggregate.

16. The method of claim 12, further comprising hydrolyzing the amine-functionalized silane and the orthosilicate with the ammonia.

17. The method of claim 16, wherein allowing the J-aggregate to become coated in a layer comprising silica comprises crosslinking the hydrolyzed amine-functionalized silane and hydrolyzed orthosilicate.

18. The method of claim 12, wherein the amine-functionalized silane comprises (3-aminopropyl) triethoxysilane (APTES).

19. The method of claim 12, wherein the orthosilicate comprises tetraethyl orthosilicate (TEOS).

20. The method of claim 11, wherein the J-aggregate is a two-dimensional (2D) J-aggregate.
